(19) United States
(12) Patent Application Publication
(10) Pub. No.: US 2025/0063919 A1
(43) Pub. Date: Feb. 20, 2025

(54) DISPLAY PANEL AND MANUFACTURING METHOD FOR THE SAME

(71) Applicant: Samsung Display Co., LTD., Yongin-si (KR)

(72) Inventors: DONGMIN LEE, Yongin-si (KR); JOONYONG PARK, Yongin-si (KR); SUKYOUNG YANG, Yongin-si (KR); HYUNEOK SHIN, Yongin-si (KR)

(21) Appl. No.: 18/754,483

(22) Filed: Jun. 26, 2024

(30) Foreign Application Priority Data
Aug. 17, 2023 (KR) 10-2023-0107914

(51) Int. Cl. H10K 59/80; H10K 59/12; H10K 59/122; H10K 71/60; H10K 102/10

(52) U.S. Cl. CPC H10K 59/80515; H10K 59/1201; H10K 59/122; H10K 59/80521; H10K 59/873; H10K 71/60; H10K 2102/102; H10K 2102/103

(57) ABSTRACT

A display panel includes a base layer, an anode disposed on the base layer, a sacrificial pattern disposed on the anode and having a sacrificial opening which exposes a portion of the upper surface of the anode, a pixel defining film disposed on the base layer and having a light-emitting opening which corresponds to the sacrificial opening, a barrier rib disposed on the pixel defining film and having a barrier rib opening which corresponds to the light-emitting opening, a light-emitting pattern disposed on the anode in the barrier rib opening, and a cathode disposed on the light-emitting pattern to be in contact with the barrier rip, wherein the sacrificial pattern includes a metal oxide which includes a first metal, indium, and zinc, the first metal including at least one of tin or gallium, and the sacrificial pattern protruding from one side of the pixel defining film.

This application claims priority to Korean Patent Application No. 10-2023-0107914, filed on Aug. 17, 2023, and all the benefits accruing therefrom under 35 U.S.C. § 119, the content of which in its entirety is herein incorporated by reference.

### BACKGROUND

### 1. Field

The invention generally relates to a display panel, and more particularly, to a display panel and a method of manufacturing a display panel with improved display quality.

### 2. Description of Related Art

Display devices such as a television, a monitor, a smartphone, and a tablet, which provide images to users, include a display panel for displaying the images. Various display panels such as a liquid crystal display panel, an organic light-emitting display panel, an electro wetting display panel, and an electrophoretic display panel are being developed.

An organic light-emitting display panel may include an anode, a cathode, and a light-emitting pattern. The light-emitting pattern is separated for each light-emitting region, and the cathode may provide a common voltage to each light-emitting region.

### SUMMARY

The invention provides a display panel having improved process reliability, wherein the display panel is configured to form a light-emitting element without using a metal mask. A method for manufacturing the display panel is further provided.

An embodiment provides a display panel including a base layer, an anode disposed on the base layer, a sacrificial pattern disposed on the anode and having a sacrificial opening which is defined therein and which exposes a portion of the upper surface of the anode, a pixel defining film disposed on the base layer to cover at least a portion of the sacrificial pattern and having a light-emitting opening which is defined therein and which corresponds to the sacrificial opening, a barrier rib disposed on the pixel defining film and having a barrier rib opening which is defined therein and which corresponds to the light-emitting opening, a light-emitting pattern disposed on the anode in the barrier rib opening and a cathode disposed on the light-emitting pattern and in contact with the barrier rip, wherein the sacrificial pattern includes a metal oxide which includes a first metal, indium, and zinc, the first metal including at least one of tin or gallium, wherein the sacrificial pattern has a shape protruding from one side of the pixel defining film.

In an embodiment, the width of the sacrificial opening may be smaller than the width of the light-emitting opening.

In an embodiment, the content of the first metal included in the sacrificial pattern may be about 5.0 at % or more of the total content of the first metal, the indium, and the zinc included in the sacrificial pattern.

In an embodiment, the sacrificial pattern may include an indium tin zinc oxide (ITZO) or an indium gallium zinc oxide (IGZO).

In an embodiment, the metal oxide included in the sacrificial pattern may include an amorphous structure.

In an embodiment, among the total content of the first metal, indium, and zinc included in the sacrificial pattern, the content of the indium may be about 35 at % to about 50 at %, and the content of the zinc may be about 35 at % to about 50 at %.

In an embodiment, the content ratio of the indium to the zinc included in the sacrificial pattern may be about 4:6 to about 6:4.

In an embodiment, the anode may include an indium tin oxide (ITO).

In an embodiment, the anode may include a first layer disposed on the base layer and including an indium tin oxide (ITO), a second layer disposed on the first layer and including silver, and a third layer disposed on the second layer and including an indium tin oxide (ITO), wherein the sacrificial pattern may be directly disposed on the third layer.

In an embodiment, the light-emitting opening may expose a portion of the upper surface of the sacrificial pattern, and the portion of the upper surface of the sacrificial pattern exposed by the light-emitting opening may be in contact with the light-emitting pattern.

In an embodiment, the barrier rib may include a first barrier rib layer disposed on the pixel defining film and including a metal and a second barrier rib layer disposed on the first barrier rib layer and including a metal or a silicon-based compound.

In an embodiment, the cathode may be in contact with the first barrier rib layer.

In an embodiment, the barrier rib opening may include a first region in which the light-emitting pattern is disposed and a second region having a smaller width than the first region, wherein an inner side surface of the first barrier rib layer may define the first region, and an inner side surface of the second barrier rib layer may define the second region.

In an embodiment, the second barrier rib layer may have an undercut shape protruding from one side of the first barrier rib layer.

In an embodiment, the display panel may further include a thin film encapsulation layer disposed on the light-emitting element and including a plurality of thin films, wherein the thin film encapsulation layer may include an inorganic encapsulation pattern which covers the light-emitting element and which is partially in contact with the barrier rib.

In an embodiment, a display panel includes a base layer, an anode disposed on the base layer, a sacrificial pattern disposed on the anode and having a sacrificial opening which is defined therein and which exposes a portion of the upper surface of the anode, a pixel defining film disposed on the base layer to cover at least a portion of the sacrificial pattern and having a light-emitting opening which is defined therein and which corresponds to the sacrificial opening, a barrier rib disposed on the pixel defining film and having a barrier rib opening which is defined therein and which corresponds to the light-emitting opening, a light-emitting pattern disposed on the anode in the barrier rib opening and a cathode disposed on the light-emitting pattern and in contact with the barrier rib, wherein the sacrificial pattern includes a first metal, indium, and zinc, the first metal including at least one of tin or gallium, wherein the content of the first metal included in the sacrificial pattern is about 5.0 at % or more of the total content of the first metal, the indium, and the zinc included in the sacrificial pattern.

In an embodiment, an inner side surface of the pixel defining film may be disposed closer to the center of the anode than an inner side surface of the sacrificial pattern.

In an embodiment, the inner side surface of the pixel defining film may be aligned with the inner side surface of the sacrificial pattern.

In an embodiment, a method of manufacturing a display panel includes forming an anode on a base layer, forming a preliminary sacrificial pattern, which includes a metal oxide including indium, zinc, and a first metal including at least one of tin or gallium, on the anode, forming a preliminary pixel defining film covering the anode and the preliminary sacrificial pattern, forming a preliminary barrier rib on the preliminary pixel defining film, etching the preliminary barrier rib to form a barrier rib having a barrier rib opening defined therein, etching the preliminary pixel defining film to form a pixel defining film having a light-emitting opening defined therein and overlapping the barrier rib opening, etching the preliminary sacrificial pattern to form a sacrificial pattern having a sacrificial opening defined therein and overlapping the barrier rib opening and forming a cathode, which is in contact with a light-emitting pattern and the barrier rib, in the barrier rib opening, wherein, in the forming of the sacrificial pattern, the sacrificial pattern is formed so as to protrude from one side of the pixel defining film.

In an embodiment, in the forming of the sacrificial pattern, an etch rate of the anode may be lower than an etch rate of the preliminary sacrificial pattern.

### BRIEF DESCRIPTION OF THE FIGURES

The accompanying drawings are included to provide a further understanding of the invention. The drawings illustrate embodiments of the invention and, together with the description, serve to explain principles of the invention. The above and other objects and features of the invention will become apparent by describing in detail embodiments thereof with reference to the accompanying drawings.

FIG. 1A is a perspective view of a display device, according to an embodiment;

FIG. 1B is an exploded perspective view of the display device, according to an embodiment;

FIG. 2 is a cross-sectional view of a display module, according to an embodiment;

FIG. 3A is a plan view of a display panel, according to an embodiment;

FIG. 3B is an equivalent circuit diagram of a pixel, according to an embodiment;

FIG. 4 is an enlarged plan view of a portion of a display region of the display panel, according to an embodiment;

FIG. 5A is a cross-sectional view of the display panel, according to an embodiment;

FIG. 5B is a cross-sectional view of the display panel, according to an embodiment;

FIG. 6 is a cross-sectional view of the display panel, according to an embodiment;

FIG. 7 is a cross-sectional view of the display panel, according to an embodiment;

FIG. 8A is a cross-sectional view illustrating steps of a method of manufacturing a display panel, according to an embodiment;

FIG. 8B is a cross-sectional view illustrating steps of a method of manufacturing a display panel, according to an embodiment;

FIG. 8C is a cross-sectional view illustrating steps of a method of manufacturing a display panel, according to an embodiment;

FIG. 8D is a cross-sectional view illustrating steps of a method of manufacturing a display panel, according to an embodiment;

FIG. 8E is a cross-sectional view illustrating steps of a method of manufacturing a display panel, according to an embodiment;

FIG. 8F is a cross-sectional view illustrating steps of a method of manufacturing a display panel, according to an embodiment;

FIG. 8G is a cross-sectional view illustrating steps of a method of manufacturing a display panel, according to an embodiment;

FIG. 8H is a cross-sectional view illustrating steps of a method of manufacturing a display panel, according to an embodiment;

FIG. 8I is a cross-sectional view illustrating steps of a method of manufacturing a display panel, according to an embodiment;

FIG. 8J is a cross-sectional view illustrating steps of a method of manufacturing a display panel, according to an embodiment;

FIG. 8K is a cross-sectional view illustrating steps of a method of manufacturing a display panel, according to an embodiment; and

FIG. 8L is a cross-sectional view illustrating steps of a method of manufacturing a display panel, according to an embodiment.

### DETAILED DESCRIPTION

In this disclosure, it will be understood that when an element (or region, layer, portion, etc.) is referred to as being “on”, “connected to” or “coupled to” another element, it can be directly on, connected or coupled to the other element, or intervening elements may be present.

Like reference numerals refer to like elements throughout. In addition, in the drawings, the thicknesses, ratios, and dimensions of components are exaggerated for effective description of the technical features. As used herein, the term “and/or” includes any and all combinations that the associated components can define.

It will be understood that, although the terms first, second, etc. may be used herein to describe various elements, these elements should not be limited by these terms. These terms are only used to distinguish one element from another element. For example, a first element could be termed a second element without departing from the scope of the invention. Similarly, the second element may also be referred to as the first element. The terms of a singular form include plural forms unless otherwise specified.

In addition, terms, such as “below”, “on”, “lower”, “above”, “upper” and the like, are used herein for ease of description to describe one element's relation to another element(s) as illustrated in the drawing. The above terms are relative concepts and are described based on the directions indicated in the drawings.

It will be understood that the terms “include”, “comprise” and/or “have”, when used in this specification, specify the presence of stated features, integers, steps, operations, elements, components and/or combinations thereof, but do not preclude the presence or addition of one or more other features, integers, steps, operations, elements, components, and/or combinations thereof.

In this specification, the expression “being directly disposed” may mean that there is no layer, film, region, plate, or the like which is added between a part of a layer, film, region, plate, or the like and another part. For example, the expression “being directly disposed” may mean being disposed between two layers or two members without an additional member such as an adhesive member interposed therebetween.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the related technology and the relevant art and will not be interpreted in an idealized or overly formal sense unless expressly so defined herein.

Terms such as “part” and “unit” mean a software component or hardware component that performs a specific function. The hardware component may include, for example, a field-programmable gate array (FPGA) or an application-specific integrated circuit (ASIC). The software component may refer to an executable code and/or data used by the executable code in an addressable storage medium. Thus, the software components may be, for example, object-oriented software components, class components, and task components, and may include processes, functions, attributes, procedures, subroutines, program code segments, drivers, firmware, microcode, circuits, data, database, data structures, tables, arrays, or variables.

Hereinafter, a display device, according to an embodiment, will be described with reference to the drawings.

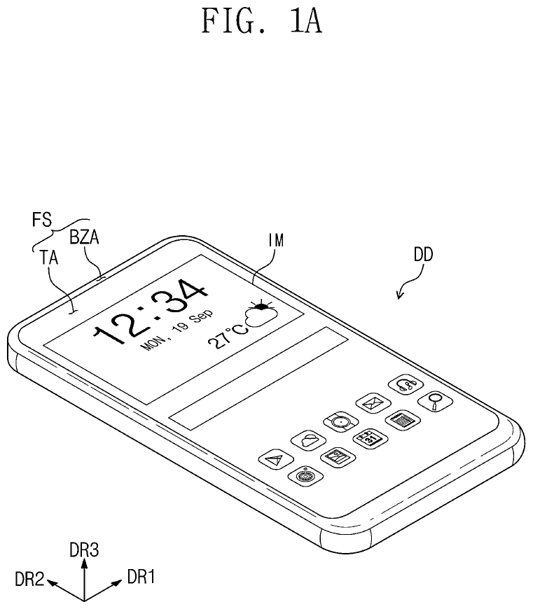

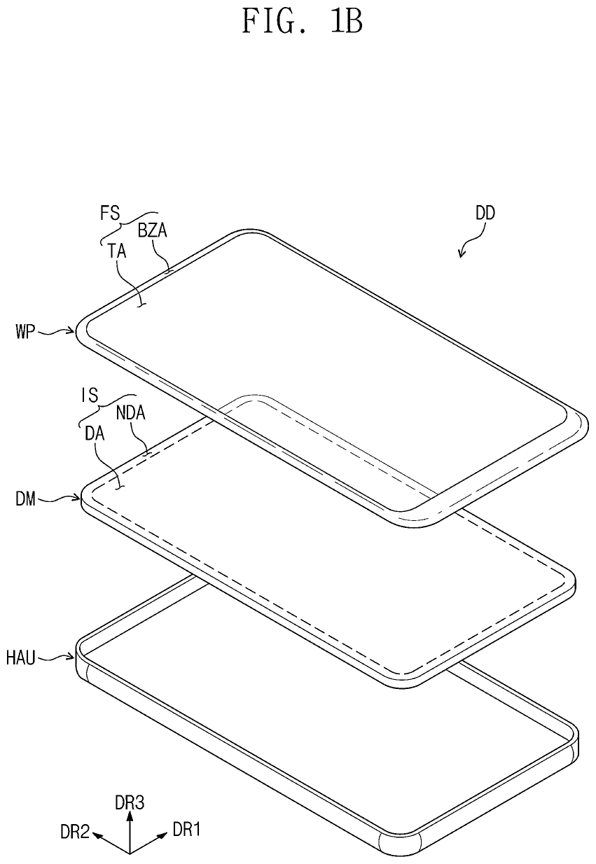

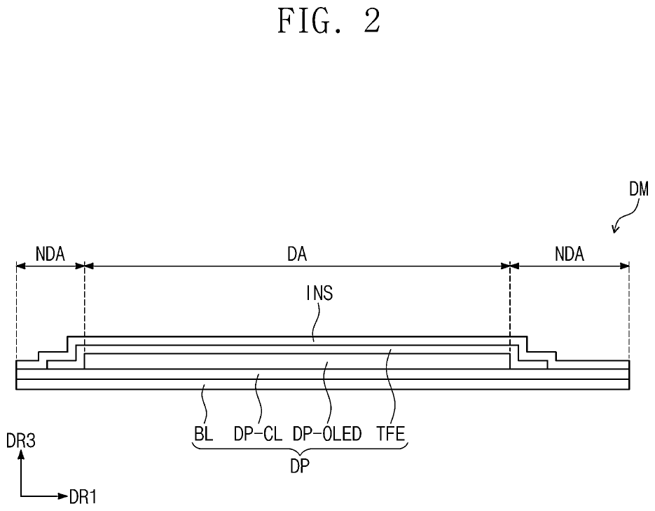

FIG. 1A is a perspective view of a display device, according to an embodiment. FIG. 1B is an exploded perspective view of the display device, according to an embodiment. FIG. 2 is a cross-sectional view of a display module, according to an embodiment.

In an embodiment, the display device DD may be a large electronic device such as a television, a monitor, or an external billboard. In addition, the display device DD may be a small or medium-sized electronic device such as a personal computer, a laptop computer, a personal digital terminal, a car navigation unit, a game console, a smartphone, a tablet, and a camera. These are presented only as examples and the display device DD may be employed as other display devices. In this embodiment, the display device DD is exemplarily illustrated as a smart phone.

In an embodiment and referring to FIGS. 1A, 1B, and 2, the display device DD may display an image IM toward a third direction DR3 on a display surface FS which is directed parallel to each of a first direction DR1 and a second direction DR2. The image IM may include a still image as well as a dynamic image. FIG. 1A illustrates a watch window and a plurality of icons as an example of the image IM. The display surface FS on which the image IM is displayed may correspond to the front surface of the display device DD.

In an embodiment, the front (or upper) and rear (or lower) surfaces of each member are defined based on a direction in which an image IM is displayed. The front and rear surfaces face each other in the third direction DR3, and a normal direction of each of the front and rear surfaces may be directed parallel to the third direction DR3. Meanwhile, directions indicated by the first to third directions DR1, DR2, and DR3, respectively, are relative concepts and may be converted into other directions. In this specification, the expression “on a plane” may mean when viewed from the third direction DR3.

In an embodiment and as illustrated in FIG. 1B, the display device DD may include a window WP, a display module DM, and a housing HAU. The window WP and the housing HAU may be coupled to each other to configure the exterior of the display device DD.

In an embodiment, the window WP may include an optically transparent insulating material. For example, the window WP may include glass or plastic. The front of the window WP may define the display surface FS of the display device DD. The display surface FS may include a transmission region TA and a bezel region BZA. The transmission region TA may be an optically transparent region. For example, the transmission region TA may have a visible light transmittance of about 90% or more.

In an embodiment, the bezel region BZA may have a relatively low light transmittance compared to the transmission region TA. The bezel region BZA may define the shape of the transmission region TA. The bezel region BZA may be disposed adjacent to the transmission region TA and may surround the transmission region TA. Meanwhile, this is exemplarily illustrated, and in the window WP, according to an embodiment, the bezel region BZA may be omitted. The window WP may include at least one functional layer among an anti-fingerprint layer, a hard coating layer, and an anti-reflection layer, but the invention is not limited to any one embodiment.

In an embodiment, the display module DM may be disposed below the window WP. The display module DM may be configured to substantially generate an image IM. The image IM generated by the display module DM is displayed on the display surface IS of the display module DM and is visually recognized by a user from the outside through the transmission region TA.

In an embodiment, the display module DM includes a display region DA and a non-display region NDA. The display region DA may be activated according to an electrical signal. The non-display region NDA is disposed adjacent to the display region DA. The non-display region NDA may surround the display region DA. The non-display region NDA may be covered by the bezel region BZA and may not be visually recognized from the outside.

In an embodiment and as illustrated in FIG. 1B, the housing HAU may be coupled to the window WP. The housing HAU may be coupled to the window WP to provide a predetermined internal space. The display module DM may be accommodated in the internal space.

In an embodiment, the housing HAU may include a material with relatively high rigidity. For example, the housing HAU may include a plurality of frames and/or plates made of glass, plastic, metal, or a combination thereof. The housing HAU may stably protect the components of the display device DD accommodated in the internal space from an external impact.

In an embodiment and referring to FIG. 2, the display module DM may include a display panel DP and an input sensor INS. Although not separately illustrated, the display device DD (see FIG. 1A), according to an embodiment, may further include a protective member disposed on the lower surface of the display panel DP or an anti-reflection member and/or a window member disposed on the upper surface of the input sensor INS.

In an embodiment, the display panel DP may be a light-emitting display panel. However, this is an example and the invention is not particularly limited thereto. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, or micro LEDs. Hereinafter, the display panel DP is described as an organic light-emitting display panel.

In an embodiment, the display panel DP may include a base layer BL, a circuit element layer DP-CL disposed on the base layer BL, a display element layer DP-OLED, and a thin film encapsulation layer TFE. The input sensor INS may be disposed directly on the thin film encapsulation layer TFE. In this specification, the expression “Component A is disposed directly on component B” means that no adhesive layer is disposed between component A and component B.

In an embodiment, the base layer BL may include at least one plastic film. The base layer BL may be a flexible substrate and include a plastic substrate, a glass substrate, a metal substrate, or an organic/inorganic composite material substrate. The display region DA and the non-display region NDA described in FIG. 1B may be equally defined in the base layer BL.

In an embodiment, the circuit element layer DP-CL may include at least one insulating layer and a circuit element. The insulating layer includes at least one inorganic layer and at least one organic layer. The circuit element includes signal lines, a pixel driving circuit, and the like.

In an embodiment, the display element layer DP-OLED may include a barrier rib and a light-emitting element. The light-emitting element may include an anode, an intermediate layer, and a cathode.

In an embodiment, the thin film encapsulation layer TFE may include a plurality of thin films. Some thin films may be disposed to improve optical efficiency, and some other thin films may be disposed to protect organic light-emitting diodes.

In an embodiment, the input sensor INS acquires the coordinate information of an external input. The input sensor INS may have a multi-layered structure. The input sensor INS may include a single-layered or multi-layered conductive layer. In addition, the input sensor INS may include a single-layered or multi-layered insulating layer. The input sensor INS may sense an external input by a capacitance method. However, this is an example and invention is not limited thereto. For example, in an embodiment, the input sensor INS may sense an external input by an electromagnetic induction method or by a pressure sensing method. Meanwhile, in another embodiment, the input sensor INS may be omitted.

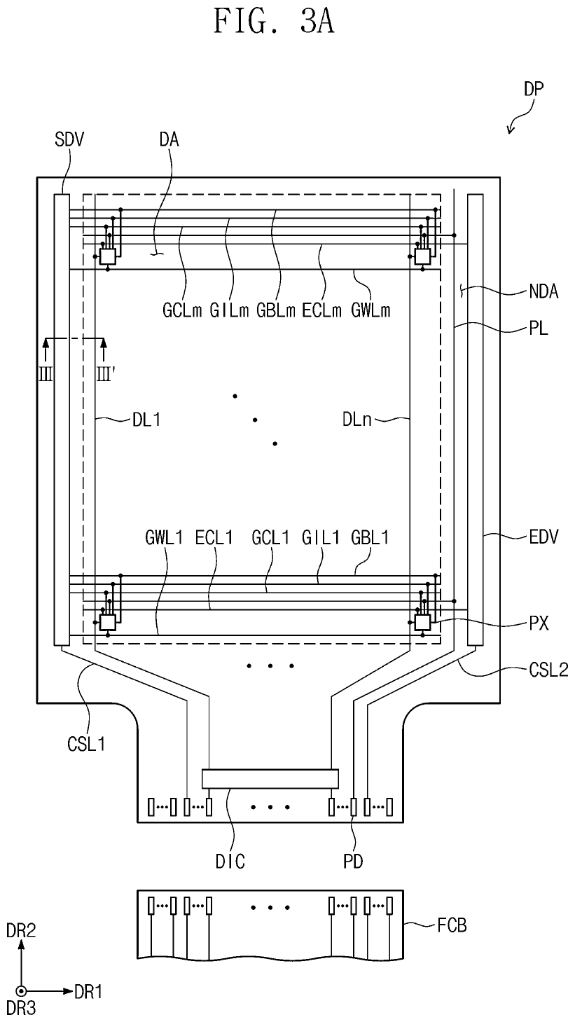

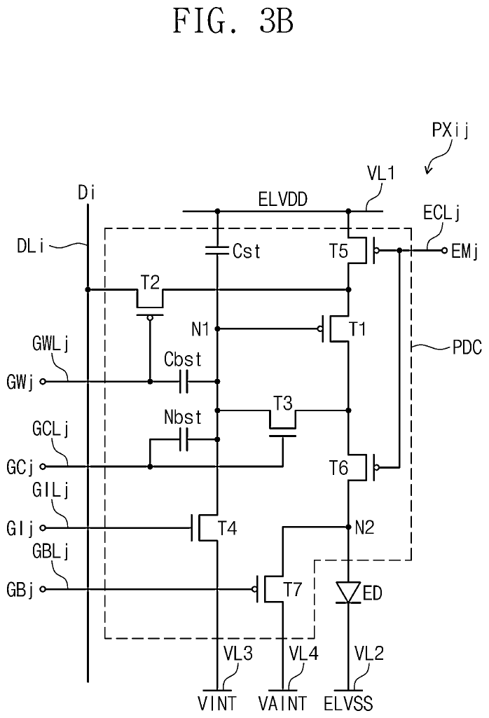

FIG. 3A is a plan view of a display panel, according to an embodiment.

In an embodiment and referring to FIG. 3A, a display region DA and a non-display region NDA surrounding the display region DA may be defined in the display panel DP. The display region DA and the non-display region NDA may be distinguished from each other according to whether or not a pixel PX are disposed. The pixel PX may be disposed in the display region DA. A scan driver SDV, a data driver, and a light-emitting driver EDV may be disposed in the non-display region NDA. The data driver may be a portion of a circuit configured in a driving chip DIC.

In an embodiment, the display panel DP may include pixels PX, initialization scan lines GIL1-GILm, compensation scan lines GCL1-GCLm, write scan lines GWL1-GWLm, black scan lines GBL1-GBLm, light-emitting control lines ECL1-ECLm, data lines DL1-DLn, first and second control lines CSL1, CSL2, respectively, a driving voltage line PL, and a plurality of pads PD. Here, m and n are natural numbers greater than or equal to 2.

In an embodiment, the pixels PX may be connected to the initialization scan lines GIL1-GILm, the compensation scan lines GCL1-GCLm, the write scan lines GWL1-GWLm, the black scan lines GBL1-GBLm, the light-emitting control lines ECL1-ECLm, and the data lines DL1-DLn.

In an embodiment, the initialization scan lines GIL1-GILm, the compensation scan lines GCL1-GCLm, the write scan lines GWL1-GWLm, and the black scan lines GBL1-GBLm may extend in the first direction DR1 to be electrically connected to the scan driver SDV. The data lines DL1-DLn may extend in the second direction DR2 to be electrically connected to the driving chip DIC. The light-emitting control lines ECL1-ECLm may extend in the first direction DR1 to be electrically connected to the light-emitting driver EDV.

In an embodiment, the driving voltage line PL may include a portion extending in the first direction DR1 and a portion extending in the second direction DR2. The portion extending in the first direction DR1 and the portion extending in the second direction DR2 may be disposed on different layers. The driving voltage line PL may provide a driving voltage to the pixels PX.

In an embodiment, the first control line CSL1 may be connected to the scan driver SDV. The second control line CSL2 may be connected to the light-emitting driver EDV.

In an embodiment, the driving chip DIC, the driving voltage line PL, the first control line CSL1, and the second control line CSL2 may be electrically connected to the pads PD. A circuit board FCB may be electrically connected to the pads PD through an anisotropic conductive adhesive layer. The pads PD may connect the circuit board FCB to the display panel DP. The pads PD may be connected to corresponding pixels PX through the driving voltage line PL, the first control line CSL1, and the second control line CSL2.

In addition, in an embodiment, the pads PD may further include input pads. The input pads may connect the circuit board FCB to the input sensor INS (see FIG. 2). Without being limited thereto, however, the input pads may be disposed on the input sensor INS and connected to the pads PD and a separate circuit board. In an embodiment, the input sensor INS may be omitted and may not further include the input pads.

FIG. 3B is an equivalent circuit diagram of a pixel, according to an embodiment.

In an embodiment, FIG. 3B exemplarily illustrates an equivalent circuit diagram of one pixel PXij among a plurality of pixels PX (see FIG. 3A). Since each of the plurality of pixels PX has a same circuit structure, the description of the circuit structure of the pixel PXij will be applied to the remaining pixels PX, and a detailed description of the remaining pixels PX will be omitted.

In an embodiment and referring to FIGS. 3A and 3B, the pixel PXij is connected to an i-th data line DLi among the data lines DL1-DLn, a j-th initialization scan line GILj among the initialization scan lines GIL1-GILm, a j-th compensation scan line GCLj among the compensation scan lines GCL1-GCLm, a j-th write scan line GWLj among the write scan lines GWL1-GWLm, a j-th black scan line GBLj among the black scan lines GBL1-GBLm, a j-th light-emitting control line ECLj among the light-emitting control lines ECL1-ECLm, first and second driving voltage lines VL1 and VL2, respectively, and first and second initialization voltage lines VL3 and VL4, respectively, wherein i is an integer of 1 to n, and j is an integer of 1 to m.

In an embodiment, the pixel PXij includes a light-emitting element ED and a pixel circuit PDC. The light-emitting element ED may be a light-emitting diode. As an example, the light-emitting element ED may be an organic light-emitting diode including an organic light-emitting layer, but the invention is not particularly limited thereto. The pixel circuit PDC may control the amount of current flowing through the light-emitting element ED in response to a data signal Di. The light-emitting element ED may emit light having a predetermined luminance in response to the amount of current provided from the pixel circuit PDC.

In an embodiment, the pixel circuit PDC may include first to seventh transistors T1, T2, T3, T4, T5, T6, and T7, respectively, and first to third capacitors Cst, Cbst, and Nbst, respectively. The configuration of the pixel circuit PDC is not limited to the embodiment illustrated in FIG. 3B. The pixel circuit PDC illustrated in FIG. 3B is only an example, and the configuration of the pixel circuit PDC may be modified and implemented.

In an embodiment, at least one of the first to seventh transistors T1, T2, T3, T4, T5, T6, and T7, respectively, may have a low-temperature polycrystalline silicon (LTPS) semiconductor layer. At least one of the first to seventh transistors T1, T2, T3, T4, T5, T6, and T7, respectively, may have an oxide semiconductor layer. For example, the third transistor T3 and fourth transistor T4 may be oxide semiconductor transistors, and the first, second, fifth, sixth, and seventh transistors T1, T2, T5, T6, and T7, respectively, may be LTPS transistors.

Specifically, in an embodiment, the first transistor T1, which directly affects the brightness of the light-emitting element ED, may be configured to include a semiconductor layer composed of highly reliable polycrystalline silicon, and through this, it is possible to implement a high-resolution display device. Meanwhile, since an oxide semiconductor has a high carrier mobility and a low leakage current, a voltage drop is not great even when a driving time is long. That is, since a color change of an image due to the voltage drop is not great even during low-frequency driving, the low-frequency driving is possible. As described above, since the oxide semiconductor has an advantage that leakage current is small, it is possible not only to prevent leakage current, which may flow to a gate electrode, but also to reduce power consumption by adopting, as an oxide semiconductor, at least one of the third transistor T3 or the fourth transistor T4 connected to the gate electrode of the first transistor T1.

In an embodiment, some of the first to seventh transistors T1, T2, T3, T4, T5, T6, and T7, respectively, may be P-type transistors, and others may be N-type transistors. For example, the first, second, fifth, sixth, and seventh transistors T1, T2, T5, T6, and T7, respectively, may be P-type transistors, and the third and fourth transistors T3 and T4, respectively, may be N-type transistors.

The configuration of the pixel circuit PDC is not limited to the embodiment illustrated in FIG. 3B. In an embodiment, the pixel circuit PDC illustrated in FIG. 3B is only an example, and the configuration of the pixel circuit PDC may be modified and implemented. For example, all of the first to seventh transistors T1, T2, T3, T4, T5, T6, and T7, respectively, may be P-type transistors or N-type transistors. Alternatively, the first, second, fifth, and sixth transistors T1, T2, T5, and T6, respectively, may be P-type transistors, and the third, fourth, and seventh transistors T3, T4, and T7, respectively, may be N-type transistors.

In an embodiment, the j-th initialization scan line GILj, the j-th compensation scan line GCLj, the j-th write scan line GWLj, the j-th black scan line GBLj, and the j-th light-emitting control line ECLj may respectively transmit, to the pixel PXij, a j-th initialization scan signal GIj, a j-th compensation scan signal GCj, a j-th write scan signal GWj, a j-th black scan signal GBj, and a j-th light-emitting control signal EMj. The i-th data line DLi transmits an i-th data signal Di to the pixel PXij. The i-th data signal Di may have a voltage level corresponding to an image signal input to the display device DD (see FIG. 1A).

In an embodiment, the first driving voltage line VL1 and the second driving voltage line VL2 may respectively transmit a first driving voltage ELVDD and a second driving voltage ELVSS to the pixel PXij. In addition, the first initialization voltage line VL3 and the second initialization voltage line VL4 may respectively transmit a first initialization voltage VINT and a second initialization voltage VAINT to the pixel PXij.

In an embodiment, the first transistor T1 is connected between the light-emitting element ED and the first driving voltage line VL1 configured to receive the first driving voltage ELVDD. The first transistor T1 includes a first electrode connected to the first driving voltage line VL1 via the fifth transistor T5, a second electrode connected to a pixel electrode (or referred to as an anode) of the light-emitting element ED via the sixth transistor T6, and a third electrode (e.g., a gate electrode) connected to one end (e.g., a first node N1) of the first capacitor Cst. The first transistor T1 may receive the i-th data signal Di transmitted from the i-th data line DLi according to the switching operation of the second transistor T2 to supply a driving current to the light-emitting element ED.

In an embodiment, the second transistor T2 is connected between the data line DLi and the first electrode of the first transistor T1. The second transistor T2 includes a first electrode connected to the data line DLi, a second electrode connected to the first electrode of the first transistor T1, and a third electrode (e.g., a gate electrode) connected to the j-th write scan line GWLj. The second transistor T2 may be turned on according to the write scan signal GWj received through the j-th write scan line GWLj and transmit the i-th data signal Di, which is received from the i-th data line DLi, to the first electrode of the first transistor T1. One end of the second capacitor Cbst may be connected to the third electrode of the second transistor T2, and the other end of the second capacitor Cbst may be connected to the first node N1.

In an embodiment, the third transistor T3 is connected between the second electrode of the first transistor T1 and the first node N1. The third transistor T3 includes a first electrode connected to the third electrode of the first transistor T1, a second electrode connected to the second electrode of the first transistor T1, and a third electrode (e.g., a gate electrode) connected to the j-th compensation scan line GCLj. The third transistor T3 may be turned on according to the j-th compensation scan signal GCj received through the j-th compensation scan line GCLj so that the third electrode of the first transistor T1 and the second electrode of the first transistor T1 are connected to each other, thus being able to diode-connect the first transistor T1. One end of the third capacitor Nbst may be connected to the third electrode of the third transistor T3, and the other end of the third capacitor Nbst may be connected to the first node N1.

In an embodiment, the fourth transistor T4 is connected between the first node N1 and the first initialization voltage line VL3 to which the first initialization voltage VINT is applied. The fourth transistor T4 includes a first electrode connected to the first initialization voltage line VL3 to which the first initialization voltage VINT is transmitted, a second electrode connected to the first node N1, and a third electrode (e.g., a gate electrode) connected to the j-th initialization scan line GILj. The fourth transistor T4 is turned on according to the j-th initialization scan signal GIj received through the j-th initialization scan line GILj. The turned-on fourth transistor T4 transmits the first initialization voltage VINT to the first node N1 to initialize the potential (i.e., the potential of the first node N1) of the third electrode of the first transistor T1.

In an embodiment, the fifth transistor T5 includes a first electrode connected to the first driving voltage line VL1, a second electrode connected to the first electrode of the first transistor T1, and a third electrode (e.g., a gate electrode) connected to the j-th light-emitting control line ECLj. The sixth transistor T6 includes a first electrode connected to the second electrode of the first transistor T1, a second electrode connected to the pixel electrode of the light-emitting element ED, and a third electrode (e.g., a gate electrode) connected to the j-th light-emitting control line ECLj.

In an embodiment, the fifth and sixth transistors T5 and T6, respectively, are simultaneously turned on according to the j-th light-emitting control signal EMj received through the j-th light-emitting control line ECLj. The first driving voltage ELVDD applied through the turned-on fifth transistor T5 may be compensated through the diode-connected first transistor T1 and then transmitted to the light-emitting element ED through the sixth transistor T6.

In an embodiment, the seventh transistor T7 includes a first electrode connected to the second initialization voltage line VL4 to which the second initialization voltage VAINT is transmitted, a second electrode connected to the second electrode of the sixth transistor T6, and a third electrode (e.g., a gate electrode) connected to the black scan line GBLj. The second initialization voltage VAINT may have a voltage level equal to or lower than that of the first initialization voltage VINT.

In an embodiment, one end of the first capacitor Cst is connected to the third electrode of the first transistor T1, and the other end of the first capacitor Cst is connected to the first driving voltage line VL1. The cathode of the light-emitting element ED may be connected to the second driving voltage line VL2 configured to transmit the second driving voltage ELVSS. The second driving voltage ELVSS may have a lower voltage level than the first driving voltage ELVDD.

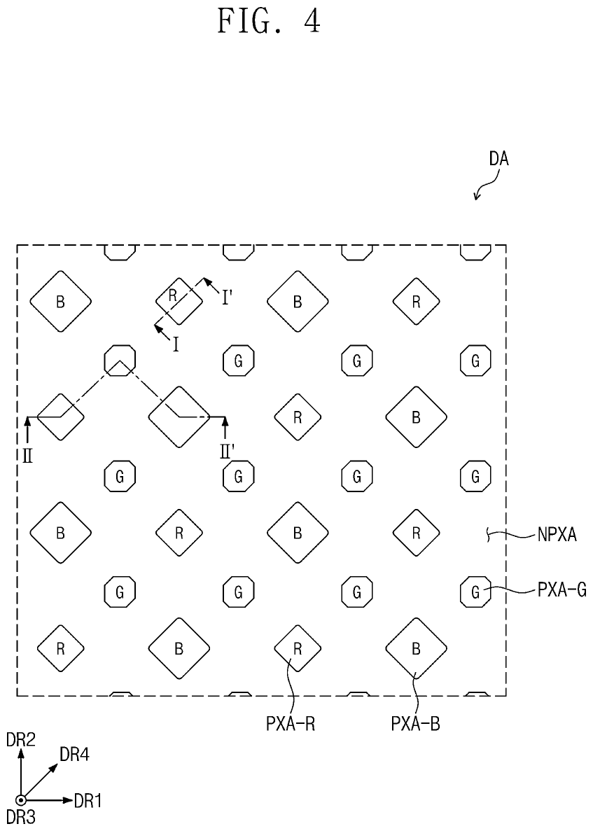

FIG. 4 is an enlarged plan view of a portion of a display region of a display panel, according to an embodiment. FIG. 4 illustrates a plane of the display module DM viewed from the display surface IS (see FIG. 1B) of the display module DM (see FIG. 1B), and shows an arrangement of light-emitting regions PXA-R, PXA-G, and PXA-B.

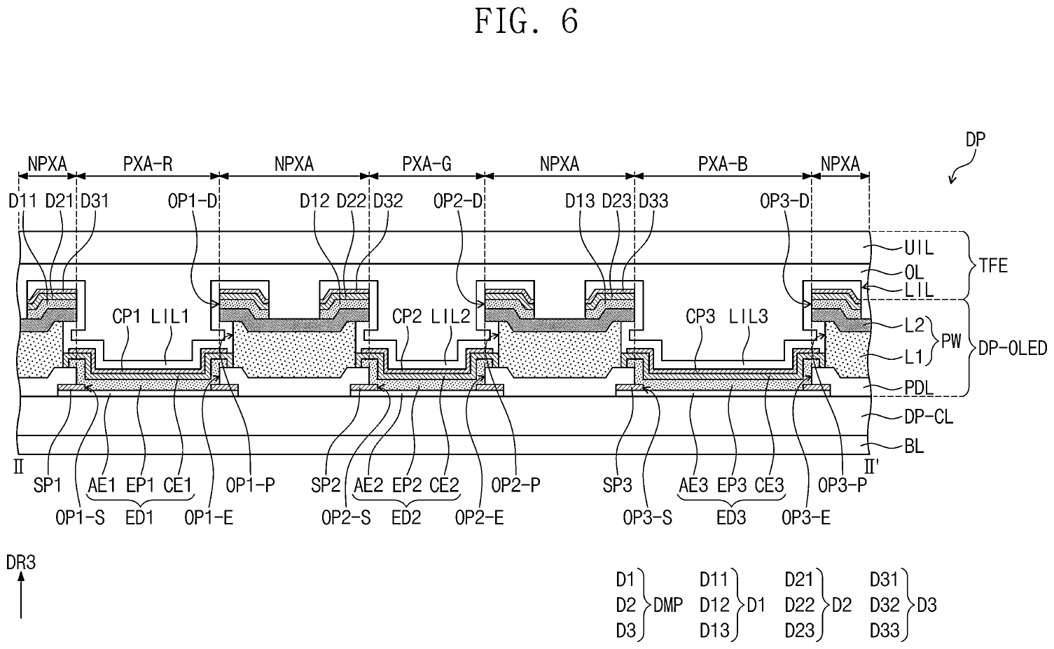

In an embodiment and referring to FIG. 4, the display region DA may include first to third light-emitting regions PXA-R, PXA-G, and PXA-B, respectively, and a peripheral region NPXA surrounding the first to third light-emitting regions PXA-R, PXA-G, and PXA-B, respectively. The first light-emitting region PXA-R, the second light-emitting region PXA-G and the third light-emitting region PXA-B may respectively correspond to regions from which light provided from light-emitting elements ED1, ED2, and ED3 (see FIG. 6) is emitted. The first to third light-emitting regions PXA-R, PXA-G, and PXA-B, respectively, may be classified according to the color of light emitted toward the outside of the display module DM (see FIG. 1B).

In an embodiment, the first light-emitting region PXA-R, the second light-emitting region PXA-G and the third light-emitting region PXA-B may respectively provide first to third color lights having different colors. For example, the first color light may be red light, the second color light may be green light, and the third color light may be blue light. However, the first to third color lights are not necessarily limited to the above examples.

In an embodiment, each of the first light-emitting region PXA-R, the second light-emitting region PXA-G and the third light-emitting region PXA-B may be defined as a region in which the upper surface of the anode is exposed through a light-emitting opening to be described later. The peripheral region NPXA sets boundaries between the first light-emitting region PXA-R, the second light-emitting region PXA-G and the third light-emitting region PXA-B and may prevent color mixing between the first light-emitting region PXA-R, the second light-emitting region PXA-G and the third light-emitting region PXA-B.

In an embodiment, each of the first light-emitting region PXA-R, the second light-emitting region PXA-G and the third light-emitting region PXA-B may be provided in plurality and they may be repeatedly arranged in a predetermined arrangement form in the display region DA. For example, the first and third light-emitting regions PXA-R and PXA-B, respectively, may be alternately arranged along the first direction DR1 to form a ‘first group’. The second light-emitting regions PXA-G may be arranged along the first direction DR1 to form a ‘second group’. Each of the ‘first group’ and the ‘second group’ may be provided in plurality, and the ‘first groups’ and the ‘second groups’ may be alternately arranged along the second direction DR2.

In an embodiment, one second light-emitting region PXA-G may be disposed to be spaced apart from one first light-emitting region PXA-R or one third light-emitting region PXA-B in a fourth direction DR4. The fourth direction DR4 may be defined as a direction between the first and second directions DR1 and DR2.

In an embodiment, FIG. 4 exemplarily illustrates an arrangement form of the first light-emitting region PXA-R, the second light-emitting region PXA-G and the third light-emitting region PXA-B, but the arrangement form thereof is not limited thereto and they may be arranged in various forms. In an embodiment, the first light-emitting region PXA-R, the second light-emitting region PXA-G and the third light-emitting region PXA-B may have a PENTILE™ arrangement form as illustrated in FIG. 4. In another embodiment, the first light-emitting region PXA-R, the second light-emitting region PXA-G and the third light-emitting region PXA-B may have a stripe arrangement form or a Diamond Pixel™ arrangement form.

In an embodiment, the first light-emitting region PXA-R, the second light-emitting region PXA-G and the third light-emitting region PXA-B may have various shapes on a plane. For example, the first light-emitting region PXA-R, the second light-emitting region PXA-G and the third light-emitting region PXA-B may have polygonal, circular, or elliptical shapes. FIG. 4 exemplarily illustrates, on a plane, the first and third light-emitting regions PXA-R and PXA-B, respectively, having a quadrangular shape (or a diamond shape) and the second light-emitting region PXA-G having an octagonal shape.

In an embodiment, the first light-emitting region PXA-R, the second light-emitting region PXA-G and the third light-emitting region PXA-B may have a same shape on a plane, or at least some of them may have different shapes. FIG. 4 exemplarily illustrates, on a plane, the first and third light-emitting regions PXA-R and PXA-B, respectively, having a same shape and the second light-emitting region PXA-G having a shape different from those of the first and third light-emitting regions PXA-R and PXA-B, respectively.

In an embodiment, at least some of the first light-emitting region PXA-R, the second light-emitting region PXA-G and the third light-emitting region PXA-B may have different areas on a plane. In an embodiment, the area of the first light-emitting region PXA-R configured to emit red light may be larger than the area of the second light-emitting region PXA-G configured to emit green light and smaller than the area of the third light-emitting region PXA-B configured to emit blue light. However, the size relationship between the areas of the first light-emitting region PXA-R, the second light-emitting region PXA-G and the third light-emitting region PXA-B according to the color of emitted light is not limited thereto and may vary depending on the design of the display module DM (see FIG. 2). In addition, without being limited thereto, the first light-emitting region PXA-R, the second light-emitting region PXA-G and the third light-emitting region PXA-B may have a same area on a plane.

In an embodiment, the shape, area, and arrangement of the first light-emitting region PXA-R, the second light-emitting region PXA-G and the third light-emitting region PXA-B of the display module DM (see FIG. 2) may be designed in various ways according to the color of emitted light or the size and configuration of the display module DM (see FIG. 2), and the invention is not limited to the embodiment illustrated in FIG. 4.

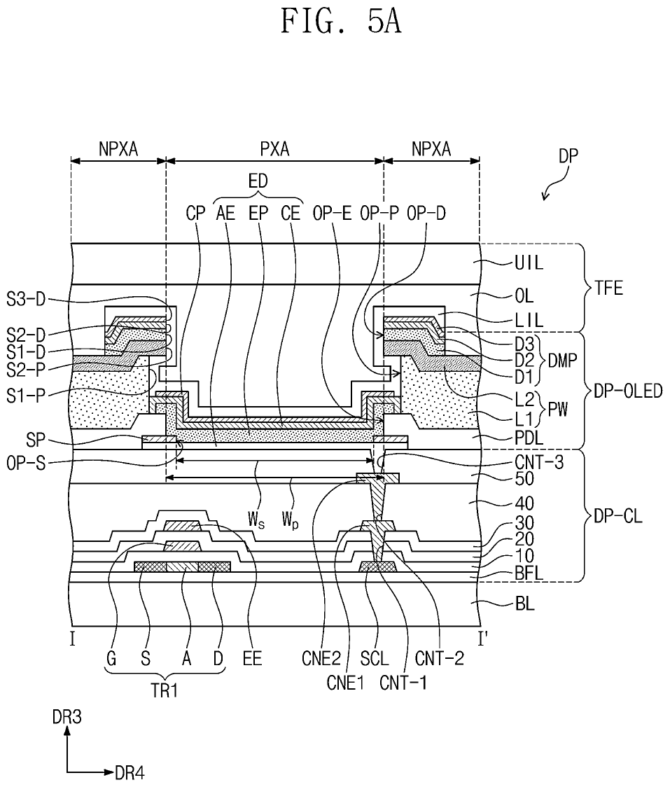

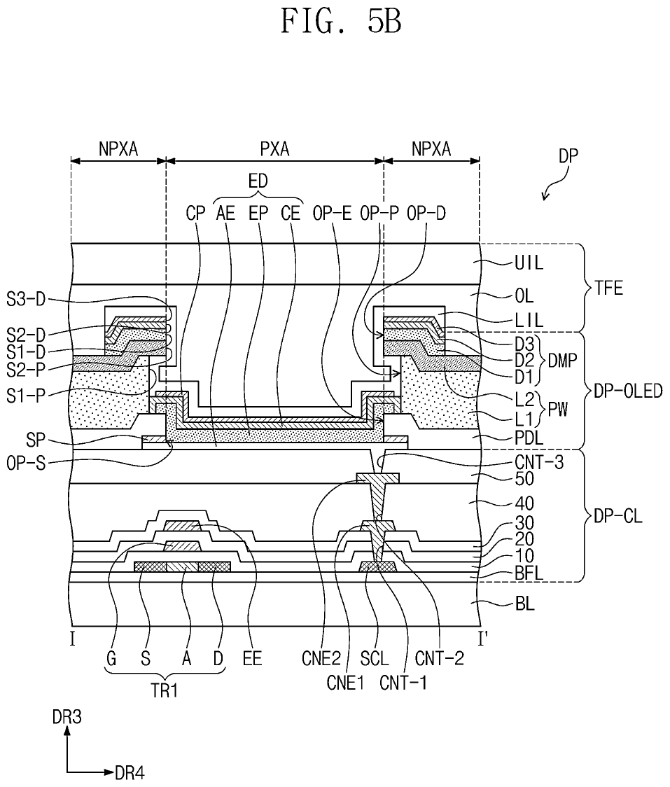

FIG. 5A is a cross-sectional view of the display panel, according to an embodiment. FIG. 5A illustrates a cross section taken along line I-I′ of FIG. 4. Meanwhile, FIG. 5A will be described with reference to FIG. 2, and the descriptions of the same reference numerals will be omitted.

In an embodiment, FIG. 5A is an enlarged view of one light-emitting region PXA in the display region DA (see FIG. 4), and the light-emitting region PXA of FIG. 5A may correspond to any one of the first light-emitting region PXA-R, the second light-emitting region PXA-G and the third light-emitting region PXA-B of FIG. 4.

In an embodiment and referring to FIG. 5A, the display panel DP may include a base layer BL, a circuit element layer DP-CL, a display element layer DP-OLED, and a thin film encapsulation layer TFE.

In an embodiment, the display panel DP may include a plurality of insulating layers, a semiconductor pattern, a conductive pattern, a signal line, and the like. An insulating layer, a semiconductor layer, and a conductive layer are formed by a method such as coating and deposition. Hereafter, the insulating layer, the semiconductor layer, and the conductive layer may be selectively patterned through photolithography and etching processes. In this way, the semiconductor pattern, the conductive pattern, the signal line, and the like included in the circuit element layer DP-CL and the display element layer DP-OLED may be formed.

In an embodiment, the circuit element layer DP-CL may be disposed on the base layer BL. The circuit element layer DP-CL may include a buffer layer BFL, a transistor TR1, a signal transmission region SCL, first to fifth insulating layers 10, 20, 30, 40, and 50, respectively, an upper electrode EE, and a plurality of connection electrodes CNE1 and CNE2.

In an embodiment, the buffer layer BFL may be disposed on the base layer BL. The buffer layer BFL may improve bonding strength between the base layer BL and the semiconductor pattern. The buffer layer BFL may include a silicon oxide layer and a silicon nitride layer. The silicon oxide layer and the silicon nitride layer may be alternately stacked on each other.

In an embodiment, the semiconductor pattern may be disposed on the buffer layer BFL. The semiconductor pattern may include polysilicon. Without being limited thereto, however, the semiconductor pattern may include amorphous silicon or a metal oxide. FIG. 5A exemplarily illustrates only a portion of the semiconductor pattern, and the semiconductor pattern may be further disposed in the plurality of light-emitting regions PXA-R, PXA-G, and PXA-B (see FIG. 4). The semiconductor pattern may be arranged in a specific rule across the plurality of light-emitting regions PXA-R, PXA-G, and PXA-B. The semiconductor pattern may have different electrical properties depending on whether it is doped or not. The semiconductor pattern may include a first region having a high doping concentration and a second region having a low doping concentration. The first region may be doped with an N-type dopant or a P-type dopant. A P-type transistor may include the first region doped with a P-type dopant.

In an embodiment, the first region has higher conductivity than the second region and substantially serves as an electrode or signal line. The second region may substantially correspond to an active (or channel) of a transistor. In other words, a portion of the semiconductor pattern may be an active of a transistor, another portion thereof may be a source or drain of a transistor, and still another portion thereof may be a conductive region.

In an embodiment, a source S, an active A, and a drain D of the transistor TR1 may be formed from the semiconductor pattern. FIG. 5A illustrates a portion of the signal transmission region SCL formed from the semiconductor pattern. Although not separately illustrated, the signal transmission region SCL may be connected to the drain D of the transistor TR1 on a plane.

In an embodiment, the first to fifth insulating layers 10, 20, 30, 40, and 50, respectively, may be disposed above the buffer layer BFL. The first to fifth insulating layers 10, 20, 30, 40, and 50, respectively, may be inorganic layers or organic layers.

In an embodiment, the first insulating layer 10 may be disposed on the buffer layer BFL. The first insulating layer 10 may cover the source S, active A, and drain D of the transistor T1 and the signal transmission region SCL which are disposed on the buffer layer BFL. A gate G of the transistor TR1 may be disposed on the first insulating layer 10. The second insulating layer 20 may be disposed on the first insulating layer 10 to cover the gate G. The upper electrode EE may be disposed on the second insulating layer 20. The third insulating layer 30 may be disposed on the second insulating layer 20 to cover the upper electrode EE.

In an embodiment, a first connection electrode CNE1 may be disposed on the third insulating layer 30. The first connection electrode CNE1 may be connected to the signal transmission region SCL through a contact hole CNT-1 passing through the first to third insulating layers 10, 20, and 30, respectively. The fourth insulating layer 40 may be disposed on the third insulating layer 30 to cover the first connection electrode CNE1. The fourth insulating layer 40 may be an organic layer.

In an embodiment, a second connection electrode CNE2 may be disposed on the fourth insulating layer 40. The second connection electrode CNE2 may be connected to the first connection electrode CNE1 through a contact hole CNT-2 passing through the fourth insulating layer 40. The fifth insulating layer 50 may be disposed on the fourth insulating layer 40 to cover the second connection electrode CNE2. The fifth insulating layer 50 may be an organic layer.

In an embodiment, the display element layer DP-OLED may be disposed on the circuit element layer DP-CL. The display element layer DP-OLED may include a light-emitting element ED, a sacrificial pattern SP, a pixel defining film PDL, a barrier rib PW, and dummy patterns DMP.

In an embodiment, the light-emitting element ED may include an anode AE (or first electrode), a light-emitting pattern EP, and a cathode CE (or second electrode). Each of first to third light-emitting elements ED1, ED2, and ED3, respectively, to be described later may have substantially the same configuration as the light-emitting element ED of FIG. 5A. The descriptions of the anode AE, the light-emitting pattern EP, and the cathode CE may be equally applied to all of the anode, the light-emitting pattern, and the cathode of each of the first to third light-emitting elements to be described later.

In an embodiment, the anode AE may be disposed on the fifth insulating layer 50 of the circuit element layer DP-CL. The anode AE may be a transmissive electrode, a semi-transmissive electrode, or a reflective electrode. The anode AE may be connected to the second connection electrode CNE2 through a connection contact hole CNT-3 defined to pass through the fifth insulating layer 50. Accordingly, the anode AE may be electrically connected to the signal transmission region SCL through the first and second connection electrodes CNE1 and CNE2, respectively, so as to be electrically connected to a corresponding circuit element.

In an embodiment, the anode AE has conductivity. The anode AE may be formed of a metal material, a metal alloy, or a conductive compound. The anode AE may include at least one selected from the group consisting of Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof. In another embodiment, the anode AE may include a transparent metal oxide, such as an indium tin oxide (ITO), an indium zinc oxide (IZO), a zinc oxide (ZnO), and an indium tin zinc oxide (ITZO). In still another embodiment, the anode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (e.g., a mixture of Ag and Mg).

In an embodiment, the anode AE may include a single-layered or multi-layered structure. The anode AE may have a single-layered structure including at least one of the above materials. For example, the anode AE may have a single-layered structure including an indium tin oxide (ITO).

In an embodiment, the anode AE may have a multi-layered structure including a plurality of layers. Each of the plurality of layers included in the anode AE may include at least one of different materials. In an embodiment, the anode AE may include a plurality of layers including an indium tin oxide (ITO) and silver (Ag). For example, the anode AE may include a first layer disposed on the base layer BL and including an indium tin oxide (ITO), a second layer disposed on the first layer and including silver (Ag), and a third layer disposed on the second layer and including an indium tin oxide (ITO).

In an embodiment, the anode AE may include a crystalline structure. The anode AE may have a crystalline structure. For example, the anode AE may have a single crystal structure or a polycrystal structure. In an embodiment, when the anode AE includes a plurality of layers, at least one of the plurality of layers included in the anode AE may include a crystalline structure. In an embodiment, the uppermost layer of the plurality of layers included in the anode AE may include a crystalline structure. That is, among the layers included in the anode AE, a layer in contact with the sacrificial pattern SP may include a crystalline structure.

In an embodiment, the thickness of the anode AE may be about 700 Å to about 10000 Å. For example, the thickness of the anode AE may be about 1000 Å to about 3000 Å.

In an embodiment, the sacrificial pattern SP may be disposed between the anode AE and the pixel defining film PDL. The sacrificial pattern SP may correspond to a portion of a layer provided to prevent the anode AE from being damaged in a process of forming a barrier rib opening OP-P which will be described later. A sacrificial opening OP-S exposing a portion of the upper surface of the anode AE may be defined in the sacrificial pattern SP. The sacrificial opening OP-S may overlap a light-emitting opening OP-E which will be described later.

In an embodiment, the pixel defining film PDL may be disposed on the fifth insulating layer 50 of the circuit element layer DP-CL. A light-emitting opening OP-E may be defined in the pixel defining film PDL. The light-emitting opening OP-E may correspond to the anode AE, and the pixel defining film PDL may expose at least a portion of the anode AE through the light-emitting opening OP-E.

In an embodiment, the light-emitting opening OP-E may correspond to the sacrificial opening OP-S of the sacrificial pattern SP. According to an embodiment, the upper surface of the anode AE may be spaced apart from the pixel defining film PDL on a cross section with the sacrificial pattern SP interposed therebetween, and therefore, in a process of forming the light-emitting opening OP-E, damage to the anode AE may be prevented.

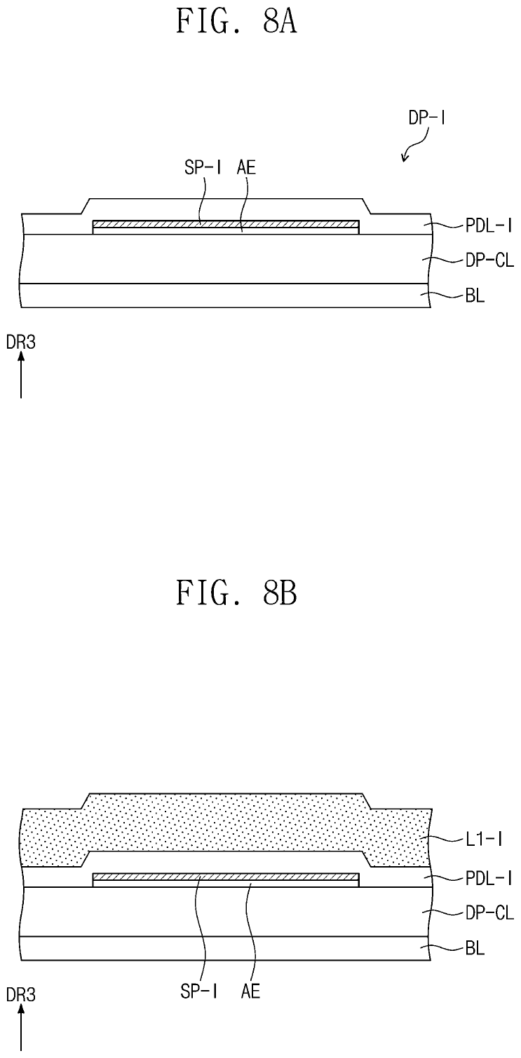

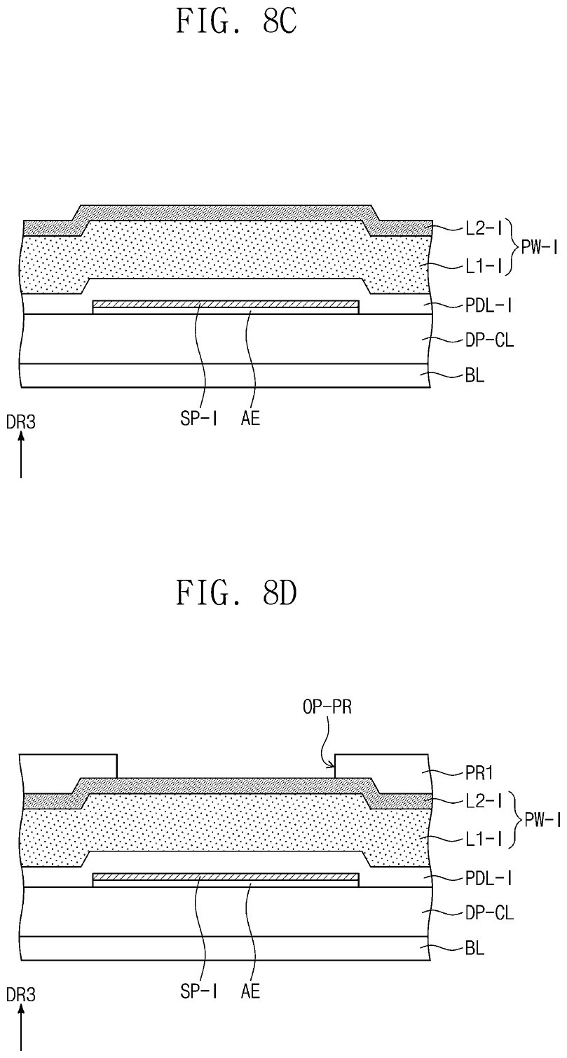

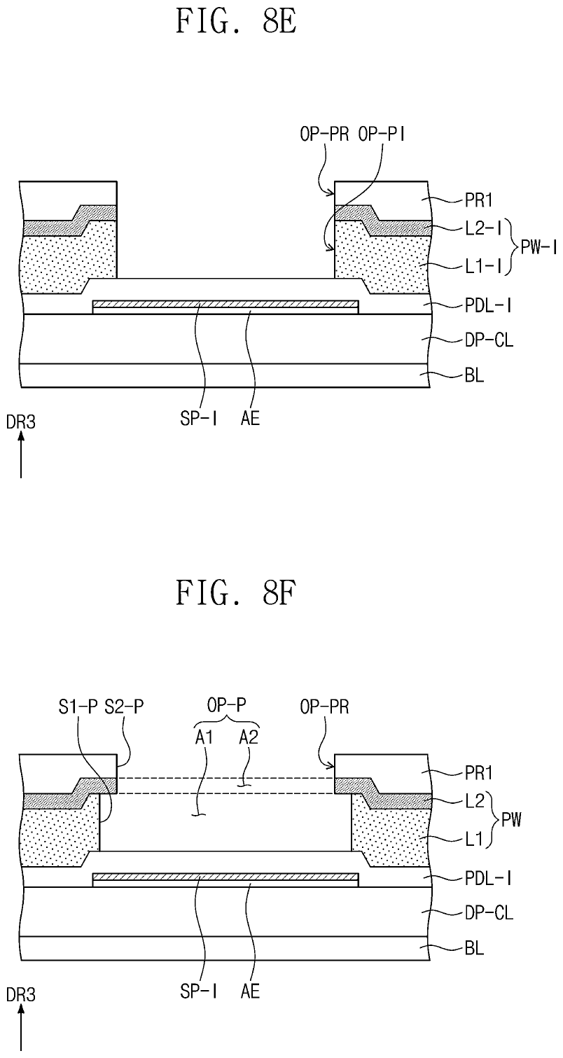

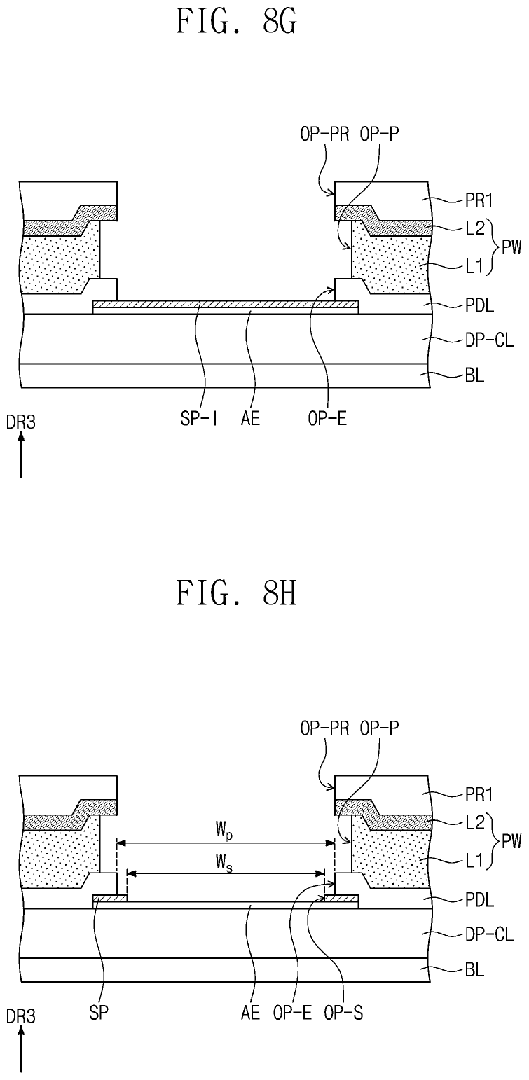

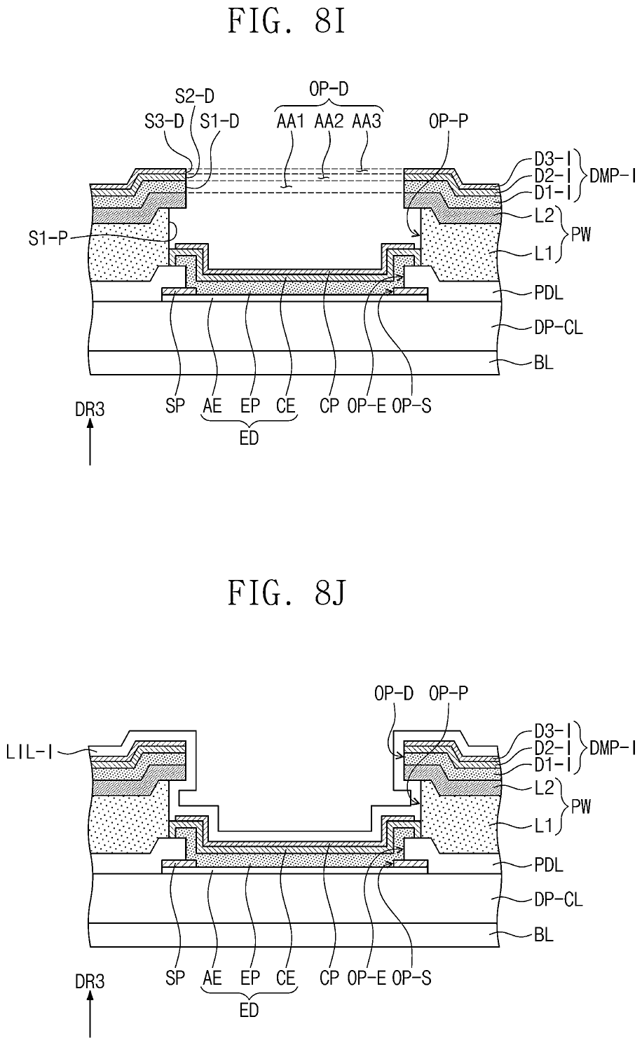

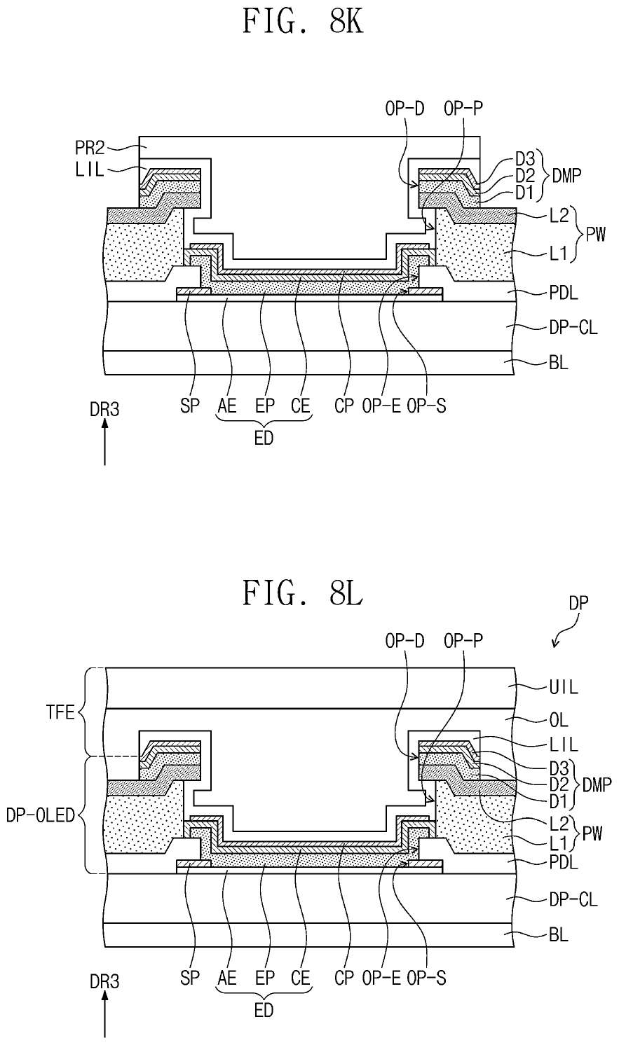

In an embodiment, the sacrificial opening OP-S may have a first width Wₛ in one direction DR4 extending from the center of the sacrificial opening OP-S to the peripheral region NPXA. The light-emitting opening OP-E may have a second width Wₚ in one direction DR4 extending from the center of the light-emitting opening OP-E to the peripheral region NPXA. In an embodiment, the first width Wₛ may be smaller than the second width Wₚ. The first width Wₛ of the sacrificial opening OP-S may be adjusted by an etch rate of a preliminary sacrificial pattern SP-I (see FIG. 8G) in forming the sacrificial pattern SP, which will be described later.

In an embodiment, when the first width Wₛ of the sacrificial opening OP-S is greater than the second width Wₚ of the light-emitting opening OP-E, a void may be formed between the anode AE and the pixel defining film PDL, thereby causing the occurrence of an image defect. Therefore, the first width Wₛ of the sacrificial opening OP-S needs to be controlled so as to be equal to or less than the second width Wₚ of the light-emitting opening OP-E. When the first width Wₛ of the sacrificial opening OP-S is controlled so as to be equal to or less than the second width Wₚ of the light-emitting opening OP-E, a defect which is caused by the occurrence of a void may be prevented. Accordingly, the reliability of the display device DD may be further improved.

In an embodiment, on a plane, the area of the sacrificial opening OP-S may be smaller than the area of the light-emitting opening OP-E. For example, the inner side surface of the sacrificial pattern SP defining the sacrificial opening OP-S may be disposed closer to the center of the anode AE than the inner side surface of the pixel defining film PDL defining the light-emitting opening OP-E.

In an embodiment, the light-emitting opening OP-E may expose a portion of the upper surface of the sacrificial pattern SP. The portion of the upper surface of the sacrificial pattern SP exposed through the light-emitting opening OP-E may be in contact with the light-emitting pattern EP.

In an embodiment, the sacrificial pattern SP includes a first metal, indium (In), and zinc (Zn). The sacrificial pattern SP may include a metal oxide including a first metal, indium, and zinc. The first metal includes at least one of tin or gallium.

In an embodiment, the sacrificial pattern SP may include a first metal-indium-zinc oxide. In an embodiment, the sacrificial pattern SP may include an indium tin zinc oxide (ITZO). For example, the sacrificial pattern SP may be composed of an indium tin zinc oxide (ITZO). In an embodiment, the sacrificial pattern SP may include an indium gallium zinc oxide (IGZO). For example, the sacrificial pattern SP may be composed of an indium gallium zinc oxide (IGZO). In another embodiment, the sacrificial pattern SP may include an indium gallium tin zinc oxide (IGTZO). For example, the sacrificial pattern SP may be composed of an indium gallium tin zinc oxide (IGTZO).

In an embodiment, the sacrificial pattern SP includes a first metal. The first metal may be an element which is included in a metal oxide layer including indium and zinc and thus affects etch rate characteristics. Among the components of the sacrificial pattern SP, the first metal may control the etch rate of the sacrificial pattern SP. The first metal included in the metal oxide layer including indium and zinc may reduce the etch rate. The etch rate may be adjusted by adjusting the percentage of the first metal included in the sacrificial pattern SP. In an embodiment, the first metal may be at least one of tin (Sn) or gallium (Ga). Meanwhile, the composition of elements included in the sacrificial pattern SP may be checked through ICP (inductively coupled plasma), XPS (X-ray photoelectron spectroscopy), SIMS (secondary ion mass spectrometry), etc.

In an embodiment, when the sacrificial pattern SP does not include the first metal, the etch rate of the metal oxide layer including indium and zinc may be increased in an etching process of the sacrificial pattern SP, thereby forming a void between the pixel defining film PDL and the anode AE. Such a void may cause not only an image defect, but also a defect in a display device. As the sacrificial pattern SP includes the first metal, excessive etching of the metal oxide layer is suppressed during the etching process of the sacrificial pattern SP, thereby preventing a defect which may be caused by the void.

In an embodiment, the content of the first metal with respect to the total content of metal elements included in the sacrificial pattern SP may be about 5 at % or more. The content of the first metal with respect to the total content of the first metal, indium, and zinc included in the sacrificial pattern SP may be about 5 at % or more. For example, the content of the first metal with respect to the total content of the first metal, indium, and zinc included in the sacrificial pattern SP may be about 5 at % to about 30 at %, preferably about 18 at % to about 25 at %. When the content of the first metal is less than about 5 at %, a void may occur between the anode AE and the pixel defining film PDL due to excessive etching of the sacrificial pattern SP during an etching process. In addition, when the content of the first metal is more than about 30 at %, the etch rate may be excessively lowered and etch uniformity may be deteriorated. When the content of the first metal satisfies the above-mentioned range, it is easy to control the etch rate, and a defect such as a void may be prevented in the etching process of the sacrificial pattern. In addition, the content of the first metal included in the sacrificial pattern SP may be appropriately adjusted within the above-mentioned range in consideration of the types, composition ratio, etching characteristics, etc. of materials included in the anode AE.

In an embodiment, the content of indium with respect to the total content of metal elements included in the sacrificial pattern SP may be about 35 at % to about 50 at %. The content of the indium with respect to the total content of the first metal, indium, and zinc included in the sacrificial pattern SP may be about 35 at % to about 50 at %.

In an embodiment, the content of zinc with respect to the total content of metal elements included in the sacrificial pattern SP may be about 35 at % to about 50 at %. The content of the zinc with respect to the total content of the first metal, indium, and zinc included in the sacrificial pattern SP may be about 35 at % to about 50 at %.

In an embodiment, the content ratio of indium to zinc in the sacrificial pattern SP may be about 4:6 to about 6:4. For example, the content ratio of the indium to the zinc in the sacrificial pattern SP may be about 5:5.

In an embodiment, the metal oxide included in the sacrificial pattern SP may have an amorphous structure. The atomic arrangement of an amorphous metal oxide may be disordered and may not have a crystalline component. Without being limited thereto, however, the sacrificial pattern SP may include a metal oxide having an amorphous structure and a crystalline structure which are mixed together.

In an embodiment, the sacrificial pattern SP may include an amorphous indium tin zinc oxide (a-ITZO), an amorphous indium gallium zinc oxide (a-IGZO), or an amorphous indium gallium tin zinc oxide (a-IGTZO). For example, the sacrificial pattern SP may be made of an amorphous indium tin zinc oxide (a-ITZO), an amorphous indium gallium zinc oxide (a-IGZO), or an amorphous indium gallium tin zinc oxide (a-IGTZO).

In an embodiment, the crystallinity of the metal oxide included in the sacrificial pattern SP may be obtained through an X-ray diffraction (XRD) analysis. For example, the crystallinity of the metal oxide included in the sacrificial pattern SP may be obtained from the peak area of the crystalline phase with respect to the sum of the peak area of the crystalline phase and the peak area of the amorphous phase in the X-ray diffraction (XRD) analysis. In this case, the peak area of the crystalline phase may be obtained from the total area of peaks representing the crystalline phase in an X-ray diffraction (XRD) pattern. In addition, the peak area of the amorphous phase may mean the area of a halo pattern in the X-ray diffraction (XRD) pattern. When the metal oxide included in the sacrificial pattern SP has an amorphous structure, a peak representing a crystal plane may not be detected in the X-ray diffraction (XRD) pattern. That is, a sharp peak corresponding to a specific value of 2θ may not appear in the X-ray diffraction (XRD) pattern. In addition, when the metal oxide has an amorphous structure, a halo pattern corresponding to a broad, gradual peak may be observed in the X-ray diffraction (XRD) pattern.

In an embodiment, the etch rate of the sacrificial pattern SP and the etch rate of the anode AE may be different from each other. The anode AE may be configured to be etched at a first etch rate, and the sacrificial pattern SP may be configured to be etched at a second etch rate which is greater than the first etch rate. In an etching process of the sacrificial pattern SP, which will be described later, the anode AE is not etched or may not be substantially etched due to the etch rate of the sacrificial pattern SP which is greater than that of the anode AE.

In an embodiment, the etch rate of the sacrificial pattern SP may be about 1.0 Å/s or more to less than about 50.0 Å/s. For example, the etch rate of the sacrificial pattern SP may be about 1.0 Å/s to about 40.0 Å/s. The “etch rate” of the sacrificial pattern SP may refer to the amount of etching per second in a film thickness direction. The “etch rate” may refer to an etch rate at room temperature (25° C.). The unit of etch rate can be expressed in Å/s. The “etch rate” of the sacrificial pattern SP may be calculated through Equation 1 below. The etch rate of the sacrificial pattern SP may be achieved by controlling the content of metals included in the sacrificial pattern SP. For example, the etch rate of the sacrificial pattern SP may be achieved by controlling the content of the first metal with respect to the total content of metal elements included in the sacrificial pattern SP.

$$Etch rate = ( {T}_{{1}^{-}} {T}_{2} ) / {S}_{1} \qquad [ Equation l ]$$

In Equation 1, T₁ refers to an initial film thickness before etching, T₂ refers to a film thickness after etching, and S₁ represents the time in seconds during which an etching solution is used for etching.

In an embodiment, the etch rate of the sacrificial pattern SP may be controlled by changing the composition of the sacrificial pattern SP. The etch rate of the sacrificial pattern SP may be controlled by changing the composition of the metal elements included in the sacrificial pattern SP. Specifically, the etch rate of the sacrificial pattern SP may be controlled by adjusting the content of the first metal, indium, and zinc included in the sacrificial pattern SP. In particular, as the first metal is a factor that controls the etching speed of the sacrificial pattern SP, the more the amount of the first metal included in the sacrificial pattern SP is, the slower the etching speed may be. For example, the higher the composition rate of the first metal is in the metal oxide layer including the first metal, the indium, and the zinc, the slower the etch rate may be. By adding the first metal to the sacrificial pattern SP, it is possible to suppress the occurrence of a void between the anode AE and the pixel defining film PDL due to excessive etching of the sacrificial pattern SP.

In an embodiment, the pixel defining film PDL may include an inorganic insulating material. The pixel defining film PDL may include at least one of silicon oxide (SiOₓ), silicon nitride (SiNₓ), or silicon oxynitride (SiOₓN_{y}). For example, the pixel defining film PDL may include silicon nitride (SiNₓ). The pixel defining film PDL may be disposed between the anode AE and the barrier rib PW to block the anode AE and the barrier rib PW from being electrically connected to each other.

In an embodiment, the barrier rib PW may be disposed on the pixel defining film PDL. A barrier rib opening OP-P may be defined in the barrier rib PW. The barrier rib opening OP-P may correspond to the light-emitting opening OP-E and expose at least a portion of the anode AE.

In an embodiment, the barrier rib PW may have an undercut shape on a cross section. The barrier rib PW may include a plurality of sequentially stacked layers, and at least one layer among the plurality of layers may be recessed compared to the other layers. At least one layer among the plurality of layers included in the barrier rib PW may protrude compared to the other layers. Accordingly, the barrier rib PW may include a tip portion.

In an embodiment, the barrier rib PW may include a first barrier rib layer L1 and a second barrier rib layer L2. The first barrier rib layer L1 may be relatively recessed with respect to the second barrier rib layer L2, based on the light-emitting region PXA. That is, the first barrier rib layer L1 may be formed by being undercut with respect to the second barrier rib layer L2.

In an embodiment, the barrier rib opening OP-P defined in the barrier rib PW may include a first region A1 (see FIG. 8F) and a second region A2 (see FIG. 8F). The first barrier rib layer L1 may include a first inner side surface S1-P defining a portion of the first region A1 (FIG. 8F) of the barrier rib opening OP-P, and the second barrier rib layer (L2) may include a second inner side surface S2-P defining the second region A2 (see FIG. 8F).

In an embodiment, the first inner side surface S1-P of the first barrier rib layer L1 may be recessed more inward than the second inner side surface S2-P of the second barrier rib layer L2. That is, the first inner side surface S1-P may be formed by being undercut with respect to the second inner side surface S2-P. The second barrier rib layer L2 protruding toward the light-emitting region PXA may define a tip portion.

In an embodiment, the width of the first region A1 (see FIG. 8F) may be different from the width of the second region A2 (see FIG. 8F). The width of the first region A1 (see FIG. 8F) may be greater than the width of the second region A2 (see FIG. 8F). In this case, the second region A2 (see FIG. 8F) of the barrier rib opening OP-P may be a region that defines a tip portion.

In an embodiment, since the second inner side surface S2-P of the second barrier rib layer L2 defining the second region A2 (see FIG. 8F) protrudes compared to the first inner side surface S1-P of the first barrier rib layer L1 defining the first region A1 (see FIG. 8F), the second inner side surface S2-P of the second barrier rib layer L2 may be disposed adjacent to the center of the anode AE. That is, compared to the first inner side surface S1-P, the second inner side surface S2-P may be disposed to be adjacent to the center of the anode AE in one direction, for example, in the fourth direction DR4.

In an embodiment, the barrier rib PW may include a first barrier rib layer L1 disposed on the pixel defining film PDL and a second barrier rib layer L2 disposed on the first barrier rib layer L1. The second barrier rib layer L2 may be configured to be etched at a first etch rate, and the first barrier rib layer L1 may be configured to be etched at a second etch rate which is higher than the first etch rate. In the undercut etching process, the inner side surface of the first barrier rib layer L1 may be etched more than the inner side surface of the second barrier rib layer L2 due to the etch rate of the first barrier rib layer L1 higher than that of the second barrier rib layer L2. In another embodiment, in the undercut etching process, the second barrier rib layer L2 is not etched or may not be substantially etched.

In an embodiment and referring again to FIG. 5A, the first barrier rib layer L1 included in the barrier rib PW may be disposed on the pixel defining film PDL. The first barrier rib layer L1 may be directly disposed on the pixel defining film PDL.

In an embodiment, the first barrier rib layer L1 includes a conductive material. The first barrier rib layer L1 may include a low-resistance metal. The first barrier rib layer L1 may include gold (Au), silver (Ag), aluminum (Al), magnesium (Mg), lithium (Li), molybdenum (Mo), copper (Cu), or an alloy thereof. For example, the first barrier rib layer L1 may include aluminum (Al). The thickness of the first barrier rib layer L1 may be about 6000 angstroms to about 100000 angstroms.

In an embodiment, as illustrated in FIG. 5A, the cathode CE is in contact with the first inner side surface S1-P of the first barrier rib layer L1 and may receive the second driving voltage ELVSS (see FIG. 3B) from the first barrier rib layer L1.

In an embodiment, the second barrier rib layer L2 may be disposed on the first barrier rib layer L1. The second barrier rib layer L2 may be directly disposed on the first barrier rib layer L1. The second barrier rib layer L2 may define a tip portion formed on the barrier rib PW. The upper surface of the second barrier rib layer L2 may form the uppermost surface of the barrier rib PW and define the upper surface of the tip portion formed on the barrier rib PW.

In an embodiment, the second barrier rib layer L2 may include a material which has lower electrical conductivity than that of the first barrier rib layer L1, but which has high strength. The second barrier rib layer L2 may include a material which has a high Young's Modulus of about 300 GPa or more. Since the second barrier rib layer L2 includes a material having a high Young's modulus, the degree of deformation of the second barrier rib layer L2 may be reduced. As the degree of deformation of the second barrier rib layer L2 forming the uppermost surface of the tip portion is reduced, the robustness of the undercut shape of the barrier rib PW may increase. Accordingly, a phenomenon in which the tip portion of the barrier rib PW is sagged may be reduced or eliminated, and a phenomenon in which the tip portion blocks the inner side surface of the barrier rib PW with which the cathode CE is in contact may be reduced or eliminated.

In an embodiment, the second barrier rib layer L2 may include a second metal or a silicon-based compound.

In an embodiment, the second barrier rib layer L2 may include a second metal. The second metal included in the second barrier rib layer L2 may include gold (Au), silver (Ag), aluminum (Al), magnesium (Mg), lithium (Li), molybdenum (Mo), titanium (Ti), copper (Cu), or an alloy thereof. The second barrier rib layer L2 may include a metal material different from that of the first barrier rib layer L1. The second barrier rib layer L2 may include, for example, titanium (Ti). The thickness of the second barrier rib layer L2 may be about 400 angstroms to about 800 angstroms.

In an embodiment, unlike the first barrier rib layer L1, the second barrier rib layer L2 may not include a metal material. The second barrier rib layer L2 may include a silicon-based compound. The second barrier rib layer L2 may include at least one of silicon oxide (SiOₓ), silicon nitride (SiNₓ), or silicon oxynitride (SiOₓN_{y}). The second barrier rib layer L2 may include, for example, silicon oxide (SiOₓ). Unlike the first barrier rib layer L1, the second barrier rib layer L2 is not in contact with the cathode CE and is configured to form a tip portion to separate the cathode CE into each light-emitting region PXA, and therefore, the second barrier rib layer L2 may include a silicone-based compound which is an insulating material.

In an embodiment, FIG. 5A exemplarily illustrates that each of the first inner side surface S1-P and the second inner side surface S2-P is perpendicular to the upper surface of the pixel defining film PDL and extends along the third direction DR3, but the invention is not limited thereto. For example, the barrier rib PW may have a tapered shape or a reverse tapered shape.

In an embodiment, the light-emitting pattern EP may be disposed on the anode AE. The light-emitting pattern EP may include a light-emitting layer including a light-emitting material. The light-emitting pattern EP may further include a hole injection layer HIL and a hole transport layer HTL disposed between the anode AE and the light-emitting layer and may further include an electron transport layer ETL and an electron injection layer EIL which are disposed on the light-emitting layer. The light-emitting pattern EP may also be referred to as an ‘organic layer’ or an ‘intermediate layer’.

In an embodiment, the light-emitting pattern EP may be patterned by the tip portion defined in the barrier rib PW. The light-emitting pattern EP may be disposed inside the sacrificial opening OP-S, the light-emitting opening OP-E, and the barrier rib opening OP-P. The light-emitting pattern EP may cover a portion of the upper surface of the pixel defining film PDL, which is exposed from the barrier rib opening OP-P.

In an embodiment, the cathode CE may be disposed on the light-emitting pattern EP. The cathode CE may be patterned by the tip portion defined in the barrier rib PW. The cathode CE may be in contact with the first inner side surface S1-P of the first barrier rib layer L1.

In an embodiment, the barrier rib PW may receive the second driving voltage ELVSS (see FIG. 3B), and accordingly, the cathode CE may receive the second driving voltage ELVSS (see FIG. 3B) as the cathode CE is electrically connected to the barrier rib PW.

According to an embodiment, the display panel DP may further include a capping pattern CP. The capping pattern CP may be disposed in the barrier rib opening OP-P and may be disposed on the cathode CE. The capping pattern CP may be patterned by the tip portion formed on the barrier rib PW.

Although FIG. 5A exemplarily illustrates an embodiment where the capping pattern CP is not in contact with the second inner side surface S2-P of the second barrier rib layer L2, the invention is not limited thereto. For example, in an embodiment the capping pattern CP may be formed to be in contact with the second inner side surface S2-P of the second barrier rib layer L2. According to another embodiment, the capping pattern CP may be omitted.

In an embodiment, the dummy patterns DMP may be disposed on the barrier rib PW. The dummy patterns DMP may include a first dummy pattern D1, a second dummy pattern D2, and a third dummy pattern D3. The first to third dummy patterns D1, D2, and D3, respectively, may be sequentially stacked along the third direction DR3 on the upper surface of the second barrier rib layer L2 of the barrier rib PW.

In an embodiment, the first dummy pattern D1 may include an organic material. For example, the first dummy pattern D1 may include the same material as the light-emitting pattern EP. The first dummy pattern D1 may be formed simultaneously with the light-emitting pattern EP through one process and may be formed separately from the light-emitting pattern EP by the undercut shape of the barrier rib PW.

In an embodiment, the second dummy pattern D2 may include a conductive material. For example, the second dummy pattern D2 may include the same material as the cathode CE. The second dummy pattern D2 may be formed simultaneously with the cathode CE through one process and may be formed separately from the cathode CE by the undercut shape of the barrier rib PW.

In an embodiment, the third dummy pattern D3 may include the same material as the capping pattern CP. The third dummy pattern D3 may be formed simultaneously with the capping pattern CP through one process and may be formed separately from the capping pattern CP by the undercut shape of the barrier rib PW.

In an embodiment, a dummy opening OP-D may be defined in the dummy patterns DMP. The dummy opening OP-D may correspond to the light-emitting opening OP-E. The dummy opening OP-D may include first to third opening regions AA1, AA2, and AA3, respectively, (see FIG. 8I) sequentially arranged in the third direction DR3. The first opening region AA1 of the dummy opening OP-D may be defined by an inner side surface S1-D of the first dummy pattern D1, the second opening region AA2 may be defined by an inner side surface S2-D of the second dummy pattern D2, and the third opening region AA3 may be defined by an inner side surface S3-D of the third dummy pattern D3. On a plane, each of the first to third dummy patterns D1, D2, and D3, respectively, may have a closed-line shape surrounding the light-emitting region PXA.

In an embodiment, FIG. 5A exemplarily illustrates that the inner side surfaces of the first to third dummy patterns D1, D2, and D3, respectively, are aligned with the second inner side surface S2-P of the second barrier rib layer L2, but the invention is not limited thereto, and the first to third dummy patterns D1, D2, and D3, respectively, may cover the second inner side surface S2-P of the second barrier rib layer L2.

In an embodiment, the thin film encapsulation layer TFE may be disposed on the display element layer DP-OLED. The thin film encapsulation layer TFE may include a lower inorganic encapsulation pattern LIL, an organic encapsulation film OL, and an upper inorganic encapsulation film UIL.

In an embodiment, the lower inorganic encapsulation pattern LIL may correspond to the light-emitting opening OP-E. The lower inorganic encapsulation pattern LIL may cover the light-emitting element ED and the dummy patterns DMP, and a portion of the lower inorganic encapsulation pattern LIL may be disposed in the barrier rib opening OP-P. According to an embodiment, the lower inorganic encapsulation pattern LIL may be in contact with each of the first inner side surface S1-P of the first barrier rib layer L1 and the second inner side surface S2-P of the second barrier rib layer L2.

In an embodiment, the organic encapsulation film OL may cover the lower inorganic encapsulation pattern LIL and provide a flat upper surface. The upper inorganic encapsulation film UIL may be disposed on the organic encapsulation film OL.

In an embodiment, the lower inorganic encapsulation pattern LIL and the upper inorganic encapsulation film UIL may protect the display element layer DP-OLED from moisture/oxygen, and the organic encapsulation film OL may protect the display element layer DP-OLED from foreign substances such as dust particles.

FIG. 5B is a cross-sectional view of the display panel, according to an embodiment. FIG. 5B illustrates a cross section taken along line I-I′ of FIG. 4, according to an embodiment. Hereinafter, in describing the display panel according to an embodiment with reference to FIG. 5B, the same reference numerals will be given to the same components as those previously described in FIG. 5A, and the detailed descriptions thereof will be omitted. FIG. 5B is an enlarged view of an embodiment of one light-emitting region PXA in the display region DA (see FIG. 4), and the light-emitting region PXA of FIG. 5B may correspond to any one of the first to third light-emitting regions PXA-R, PXA-G, and PXA-B of FIG. 4.

In an embodiment and referring to FIG. 5B, when compared to the display panel illustrated in FIG. 5A, the display panel has a difference in that the inner side surface of the sacrificial pattern SP defining the sacrificial opening OP-S is aligned with the inner side surface of the pixel defining film PDL defining the light-emitting opening OP-E.

In an embodiment and referring to FIG. 5B, the first width of the sacrificial opening OP-S defined in the sacrificial pattern SP may be substantially equal to the second width of the light-emitting opening OP-E defined in the pixel defining film PDL. The first width may refer to the width of the sacrificial opening OP-S passing through the center of the sacrificial opening OP-S in the fourth direction DR4. The second width may refer to the width of the light-emitting opening OP-E passing through the center of the light-emitting opening OP-E in the fourth direction DR4. The first width of the sacrificial pattern SP may be adjusted by the etch rate of the preliminary sacrificial pattern SP-I (see FIG. 8G) in forming the sacrificial pattern SP, which will be described later.

In an embodiment, when the first width of the sacrificial opening OP-S is greater than the second width of the light-emitting opening OP-E, a void may be formed between the anode AE and the pixel defining film PDL, thereby causing an image defect or the like. Therefore, the first width Ws of the sacrificial opening OP-S needs to be controlled so as to be equal to or less than the second width Wp of the light-emitting opening OP-E. When the first width Ws of the sacrificial opening OP-S is controlled so as to be equal to or less than the second width Wp of the light-emitting opening OP-P, a defect due to the occurrence of a void may be prevented. Accordingly, the reliability of the display device DD may be further improved.

In an embodiment, on a plane, the area of the sacrificial opening OP-S may be substantially equal to the area of the light-emitting opening OP-E. The inner side surface of the sacrificial pattern SP defining the sacrificial opening OP-S and the inner side surface of the pixel defining film PDL defining the light-emitting opening OP-E may be aligned with each other in the third direction DR3.

FIG. 6 is a cross-sectional view of the display panel, according to an embodiment. FIG. 6 is a cross-sectional view taken along line II-II′ of FIG. 4. FIG. 6 is an enlarged view of one first light-emitting region PXA-R, one second light-emitting region PXA-G, and one third light-emitting region PXA-B, and the description of the light-emitting region PXA of FIG. 5A may be equally applied to each of the first to third light-emitting regions PXA-R, PXA-G, and PXA-B, respectively.

In an embodiment and referring to FIG. 6, the display panel DP may include a base layer BL, a circuit element layer DP-CL, a display element layer DP-OLED, and a thin film encapsulation layer TFE. The display element layer DP-OLED may include light-emitting elements ED1, ED2, and ED3, sacrificial patterns SP1, SP2, and SP3, a pixel defining film PDL, a barrier rib PW, and dummy patterns DMP. Meanwhile, each of the sacrificial patterns SP1, SP2, and SP3 may include substantially the same components as the sacrificial pattern SP described in FIG. 5A or 5B. The contents described for the sacrificial pattern SP in FIGS. 5A and 5B may be equally applied to the sacrificial patterns SP1, SP2, and SP3.

In an embodiment, the light-emitting elements ED1, ED2, and ED3 may include a first light-emitting element ED1, a second light-emitting element ED2, and a third light-emitting element ED3. The first light-emitting element ED1 may include a first anode AE1, a first light-emitting pattern EP1, and a first cathode CE1. The second light-emitting element ED2 may include a second anode AE2, a second light-emitting pattern EP2, and a second cathode CE2. The third light-emitting element ED3 may include a third anode AE3, a third light-emitting pattern EP3, and a third cathode CE3. The first to third anodes AE1, AE2, and AE3 may be provided as a plurality of patterns. In an embodiment, the first light-emitting pattern EP1 may provide red light, the second light-emitting pattern EP2 may provide green light, and the third light-emitting pattern EP3 may provide blue light.

In an embodiment, first to third light-emitting openings OP1-E, OP2-E, and OP3-E, respectively, may be defined in the pixel defining film PDL. The first light-emitting opening OP1-E may expose at least a portion of the first anode AE1. The first light-emitting region PXA-R may be defined as a region exposed through the first light-emitting opening OP1-E among the upper surface of the first anode AE1. The second light-emitting opening OP2-E may expose at least a portion of the second anode AE2. The second light-emitting region PXA-G may be defined as a region exposed through the second light-emitting opening OP2-E among the upper surface of the second anode AE2. The third light-emitting opening OP3-E may expose at least a portion of the third anode AE3. The third light-emitting region PXA-B may be defined as a region exposed through the third light-emitting opening OP3-E among the upper surface of the third anode AE3.

In an embodiment, the sacrificial patterns SP1, SP2, and SP3 may include a first sacrificial pattern SP1, a second sacrificial pattern SP2, and a third sacrificial pattern SP3. The first sacrificial pattern SP1, the second sacrificial pattern SP2 and the third sacrificial pattern SP3 may be respectively disposed on the upper surfaces of the first anode AE1, the second anode AE2, and the third anode AE3. The first sacrificial opening OP1-S, the second sacrificial opening OP2-S and the third sacrificial opening OP3-S respectively corresponding to the first to third light-emitting openings OP1-E, OP2-E, and OP3-E, respectively, may be defined in the first to third sacrificial patterns SP1, SP2, and SP3, respectively.

In an embodiment, the widths of the sacrificial openings OP1-S, OP2-S, and OP3-S may be smaller than the widths of the corresponding light-emitting openings OP1-E, OP2-E, and OP3-E. The width of the first sacrificial opening OP1-S passing through the center of the first sacrificial opening OP1-S in one direction may be smaller than the width of the first light-emitting opening OP1-E passing through the center of the first light-emitting opening OP1-E in one direction. The width of the second sacrificial opening OP2-S passing through the center of the second sacrificial opening OP2-S in one direction may be smaller than the width of the second light-emitting opening OP2-E passing through the center of the second light-emitting opening OP2-E in one direction. The width of the third sacrificial opening OP3-S passing through the center of the third sacrificial opening OP3-S in one direction may be smaller than the width of the third light-emitting opening OP3-S passing through the center of the third light-emitting opening OP3-E in one direction. The width of each of the sacrificial openings OP1-S, OP2-S, and OP3-S may be adjusted by the etch rate of each of the first to third sacrificial patterns SP1, SP2, and SP3, respectively, in forming the first to third sacrificial patterns SP1, SP2, and SP3, respectively.

In an embodiment, on a plane, the areas of the sacrificial openings OP1-S, OP2-S, and OP3-S may be equal to or smaller than the areas of the corresponding light-emitting openings OP1-E, OP2-E, and OP3-E. On a plane, the area of the first sacrificial opening OP1-S may be equal to or smaller than the area of the first light-emitting opening OP1-E. On a plane, the area of the second sacrificial opening OP2-S may be equal to or smaller than the area of the second light-emitting opening OP2-E. On a plane, the area of the third sacrificial opening OP3-S may be equal to or smaller than the area of the third light-emitting opening OP3-E.

In an embodiment, each of the inner side surfaces of the sacrificial patterns SP1, SP2, and SP3 defining the sacrificial openings OP1-S, OP2-S, and OP3-S may be closer to the center of the anode AE than the inner side surface of the pixel defining film PDL defining the light-emitting opening OP-E. In another embodiment, each of the inner side surfaces of the sacrificial patterns SP1, SP2, and SP3 defining the sacrificial openings OP1-S, OP2-S, and OP3-S may be aligned with the inner side surface of the pixel defining film PDL defining the light-emitting opening OP-E.

In an embodiment, the light-emitting openings OP1-E, OP2-E, and OP3-E may expose portions of the upper surfaces of the corresponding sacrificial openings OP1-S, OP2-S, and OP3-S. The first light-emitting opening OP1-E may expose a portion of the upper surface of the first sacrificial opening OP1-S. The upper surface of the first sacrificial opening OP1-S exposed by the first light-emitting opening OP1-E may be in contact with the first light-emitting pattern EP1. The second light-emitting opening OP2-E may expose a portion of the upper surface of the second sacrificial opening OP2-S. The upper surface of the second sacrificial opening OP2-S exposed by the second light-emitting opening OP2-E may be in contact with the second light-emitting pattern EP2. The third light-emitting opening OP3-E may expose a portion of the upper surface of the third sacrificial opening OP3-S. The upper surface of the third sacrificial opening OP3-S exposed by the third light-emitting opening OP3-E may be in contact with the third light-emitting pattern EP3.

In an embodiment, the first barrier rib opening OP1-P, the second barrier rib opening OP2-P and the third barrier rib opening OP3-P respectively corresponding to the first to third light-emitting openings OP1-E, OP2-E, and OP3-E, respectively, may be defined in the barrier rib PW. Each of the first to third barrier rib openings OP1-P, OP2-P, and OP3-P, respectively, may include a first region A1 (see FIG. 8F) and a second region A2 (see FIG. 8F) which are described above in FIG. 5A. The first barrier rib layer L1 may include the first inner side surfaces S1-P (see FIG. 5A) defining portions of the first regions A1 of the first to third barrier rib openings OP1-P, OP2-P, and OP3-P. The second barrier rib layer L2 may include the second inner side surfaces S2-P (see FIG. 5A) defining the second regions A2 of the first to third barrier rib openings OP1-P, OP2-P, and OP3-P, respectively.

In an embodiment, the first light-emitting pattern EP1 and the first cathode CE1 may be disposed in the first barrier rib opening OP1-P, the second light-emitting pattern EP2 and the second cathode CE2 may be disposed in the second barrier rib opening OP2-P, and the third light-emitting pattern EP3 and the third cathode CE3 may be disposed in the third barrier rib opening OP3-P. Each of the first to third cathodes CE1, CE2, and CE3, respectively, may be in contact with the first inner side surface S1-P of the first barrier rib layer L1.

In an embodiment, the first to third cathodes CE1, CE2, and CE3, respectively, are physically separated by the second barrier rib layer L2 which forms a tip portion, are respectively formed in the light-emitting openings OP1-E, OP2-E, and OP3-E, and are electrically connected to each other by being in contact with the first barrier rib layer L1, thereby being able to receive a common voltage. The first barrier rib layer L1 in contact with each of the first to third cathodes CE1, CE2, and CE3, respectively, has a relatively higher electrical conductivity than the second barrier rib layer L2, and therefore, it is possible to reduce contact resistance with the first to third cathodes CE1, CE2, and CE3, respectively. Accordingly, a common cathode voltage may be uniformly provided to the light-emitting regions PXA-R, PXA-G, and PXA-B.

According to an embodiment, the plurality of light-emitting patterns EP1, EP2, and EP3 may be patterned and deposited in pixel units by the tip portion defined in the barrier rib PW. That is, the plurality of light-emitting patterns EP1, EP2, and EP3 are commonly formed by using an open mask, but they may be easily divided into pixel units by the barrier rib PW.

In an embodiment, when the plurality of light-emitting patterns EP1, EP2, and EP3 are patterned by using a fine metal mask FMM, a support spacer protruding from a conductive barrier rib should be provided to support the fine metal mask. In addition, since the fine metal mask is spaced apart from a base surface, on which patterning is performed, by as much as the height of the barrier rib and the spacer, there may be a limitation in implementing high resolution. In addition, as the fine metal mask is in contact with the spacer, foreign substances may remain on the spacer after the patterning process of the plurality of light-emitting patterns EP1, EP2, and EP3, or the spacer may be damaged by being stabbed by the fine metal mask. Accordingly, a defective display panel may be formed.

According to an embodiment, as the barrier rib PW is included, physical separation between the light-emitting elements ED1, ED2, and ED3 may be easily achieved. Accordingly, it is possible not only to prevent a current leakage or a driving error between adjacent light-emitting regions PXA-R, PXA-G, and PXA-B, but also to drive each of the light-emitting elements ED1, ED2, and ED3 independently.

In an embodiment, by patterning the plurality of light-emitting patterns EP1, EP2, and EP3 without a mask in contact with internal components in the display region DA (see FIG. 1B), a defect rate may be reduced, thus making it possible to provide the display panel DP having improved process reliability. Since patterning is possible even when a separate support spacer protruding from the barrier rib PW is not provided, the areas of the light-emitting regions PXA-R, PXA-G, and PXA-B may be minimized and therefore, it is possible to provide the display panel DP capable of easily achieving high resolution.

In an embodiment, in manufacturing the display panel DP having a large area, a process cost may be reduced by omitting the manufacture of a mask having a large area, and it is possible to provide the display panel DP having improved process reliability by not being affected by a defect which may occur in a large-area mask.

In an embodiment, the capping patterns CP1, CP2, and CP3 may include a first capping pattern CP1, a second capping pattern CP2, and a third capping pattern CP3. The first capping pattern CP1, the second capping pattern CP2 and the third capping pattern CP3 may be respectively disposed on the first to third cathodes CE1, CE2, and CE3, respectively, in the first to third barrier rib openings OP1-P, OP2-P, and OP3-P, respectively.

In an embodiment, the dummy patterns DMP may include a plurality of first dummy patterns D1, a plurality of second dummy patterns D2, and a plurality of third dummy patterns D3.

In an embodiment, the first dummy patterns D1 may include a (1-1)-th dummy pattern D11, a (1-2)-th dummy pattern D12 and a (1-3)-th dummy pattern D13 respectively surrounding the first to third light-emitting patterns EP1, EP2, and EP3, respectively, on a plane. The (1-1)-th dummy pattern D11, the (1-2)-th dummy pattern D12 and the (1-3)-th dummy pattern D13 may respectively include the same material as the first to third light-emitting patterns EP1, EP2, and EP3, respectively, and may be formed through the same process as the first to third light-emitting patterns EP1, EP2, and EP3, respectively.

In an embodiment, the second dummy patterns D2 may include a (2-1)-th dummy pattern D21, a (2-2)-th dummy pattern D22 and a (2-3)-th dummy pattern D23 respectively surrounding the first to third light-emitting patterns EP1, EP2, and EP3, respectively, on a plane. The (2-1)-th dummy pattern D21, the (2-2)-th dummy pattern D22 and the (2-3)-th dummy pattern D23 may respectively include the same material as the first to third cathodes CE1, CE2, and CE3, respectively, and may be formed through the same process as the first to third cathodes CE1, CE2, and CE3, respectively.

In an embodiment, the third dummy patterns D3 may include a (3-1)-th dummy pattern D31, a (3-2)-th dummy pattern D32 and a (3-3)-th dummy pattern D33 respectively surrounding the first to third light-emitting patterns EP1, EP2, and EP3, respectively, on a plane. The (3-1)-th dummy pattern D31, the (3-2)-th dummy pattern D32 and the (3-3)-th dummy pattern D33 may respectively include the same material as the first to third capping patterns CP1, CP2, and CP3, respectively, and may be formed through the first to third capping patterns CP1, CP2, and CP3, respectively.

In an embodiment, the first dummy opening OP1-D, the second dummy opening OP2-D and the third dummy opening OP3-D respectively corresponding to the first to third light-emitting openings OP1-E, OP2-E, and OP3-E, respectively, may be defined in the dummy patterns DMP. Each of the first to third dummy openings OP1-D, OP2-D, and OP3-D, respectively, may include first to third opening regions AA1, AA2, and AA3, respectively, (see FIG. 8I) sequentially arranged in the third direction DR3. The first dummy opening OP1-D may be defined by the inner side surfaces of the (1-1)-th, (2-1)-th, and (3-1)-th dummy patterns D11, D21, and D31, respectively, the second dummy opening OP2-D may be defined by the inner side surfaces of the (1-2)-th, (2-2)-th, and (3-2)-th dummy patterns D12, D22, and D32, respectively, and the third dummy opening OP3-D may be defined by the inner side surfaces of the (1-3)-th, (2-3)-th, and (3-3)-th dummy patterns D13, D23, and D33, respectively.

In an embodiment, the thin film encapsulation layer TFE may include lower inorganic encapsulation patterns LIL1, LIL2, and LIL3, an organic encapsulation film OL, and an upper inorganic encapsulation film UIL. In an embodiment, the lower inorganic encapsulation patterns LIL1, LIL2, and LIL3 may include a first lower inorganic encapsulation pattern LIL1, a second lower inorganic encapsulation pattern LIL2, and a third lower inorganic encapsulation pattern LIL3. The first lower inorganic encapsulation pattern LIL1, the second lower inorganic encapsulation pattern LIL2, and the third lower inorganic encapsulation pattern LIL3 may respectively correspond to the first to third light-emitting openings OP1-E, OP2-E, and OP3-E, respectively.

In an embodiment, the first lower inorganic encapsulation pattern LIL1 may cover the first light-emitting element ED1 and the (1-1)-th, (2-1)-th, and (3-1)-th dummy patterns D11, D21, and D31, respectively, and a portion thereof may be disposed inside the first barrier rib opening OP1-P. The second lower inorganic encapsulation pattern LIL2 may cover the second light-emitting element ED2 and the (1-2)-th, (2-2)-th, and (3-2)-th dummy patterns D12, D22, and D32, respectively, and a portion thereof may be disposed inside the second barrier rib opening OP2-P. The third lower inorganic encapsulation pattern LIL3 may cover the third light-emitting element ED3 and the (1-3)-th, (2-3)-th, and (3-3)-th dummy patterns D13, D23, and D33, respectively, and a portion thereof may be disposed inside the third barrier rib opening OP3-P. The first to third lower inorganic encapsulation patterns LIL1, LIL2, and LIL3, respectively, may be provided in the form of patterns spaced apart from each other.

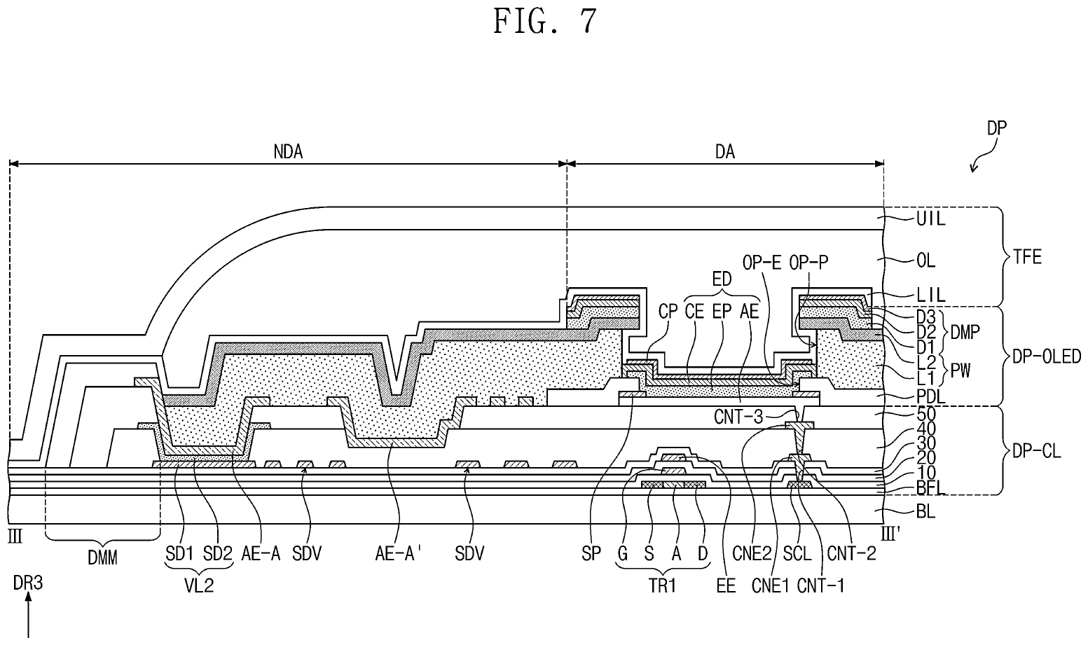

FIG. 7 is a cross-sectional view of the display panel taken along line III-III′ of FIG. 3A, according to an embodiment. FIG. 7 is an enlarged view illustrating the display panel DP including a non-display region NDA and a display region DA disposed adjacent to the non-display region NDA. The same/similar reference numerals will be used for the same/similar components as those described with reference to FIGS. 1A to 6, and duplicate descriptions will be omitted.

In an embodiment and referring to FIG. 7, the second driving voltage line VL2 may be disposed in the non-display region NDA. In an embodiment, the second driving voltage line VL2 may include a plurality of layers. For example, the second driving voltage line VL2 may include a first electrode layer SD1 and a second electrode layer SD2.

In an embodiment, the first electrode layer SD1 may be disposed on the third insulating layer 30. The first electrode layer SD1 may be formed through the same process, include the same material, and have the same structure as the first connection electrode CNE1. At least a portion of the first electrode layer SD1 may be exposed from the fourth insulating layer 40, the fifth insulating layer 50, and the pixel defining film PDL.

In an embodiment, the second electrode layer SD2 may cover an end of the fourth insulating layer 40 and be disposed on the first electrode layer SD1 exposed from the fourth insulating layer 40. That is, the second electrode layer SD2 is disposed to be in contact with the upper surface of the first electrode layer SD1 and thus may be electrically connected to the first electrode layer SD1. The second electrode layer SD2 may be formed through the same process, include the same material, and have the same structure as the second connection electrode CNE2.

Without being limited thereto, however, in an embodiment, the second driving voltage line VL2 may include only one of the first electrode layer SD1 and the second electrode layer SD2.

In an embodiment, an auxiliary electrode AE-A may be disposed on the second driving voltage line VL2. Specifically, the auxiliary electrode AE-A may cover an end of the fifth insulating layer 50 and be disposed on the second electrode layer SD2. That is, the auxiliary electrode AE-A is disposed to be in contact with the upper surface of the second electrode layer SD2 and thus may be electrically connected to the second driving voltage line VL2. The auxiliary electrode AE-A may be formed through the same process, include the same material, and have the same configuration as the anode AE. In an embodiment, the auxiliary electrode AE-A may include ITO/Ag/ITO.

In an embodiment, the barrier rib PW may overlap the non-display region NDA. The barrier rib PW may extend from the display region DA to a portion of the non-display region NDA in which the second driving voltage line VL2 is disposed. The barrier rib PW may be in direct contact with the auxiliary electrode AE-A disposed on the second driving voltage line VL2. Accordingly, the barrier rib PW may receive the second driving voltage ELVSS (see FIG. 3B) from the second driving voltage line VL2 through the auxiliary electrode AE-A, and the cathode CE in contact with the barrier rib PW in the display region DA may receive the second driving voltage ELVSS (see FIG. 3B) through the barrier rib PW. According to an embodiment, as the second driving voltage ELVSS (see FIG. 3B) is transmitted to the cathode CE through the barrier rib PW having a relatively large thickness, a voltage drop phenomenon may be reduced.

In an embodiment, the scan driver SDV may include a plurality of thin film transistors formed through the same process as the conductive patterns of the pixel circuit PDC (see FIG. 3B). FIG. 7 exemplarily illustrates that the thin film transistors constituting the scan driver SDV are disposed on the third insulating layer 30, according to an embodiment.

In an embodiment, a dam DMM may be disposed in the non-display region NDA. The dam DMM may be composed of a plurality of insulating layers. For example, the dam DMM may include a first layer formed in the same process as the fourth insulating layer 40, a second layer formed in the same process as the fifth insulating layer 50, and a third layer formed in the same process as the pixel defining film PDL. Without being limited thereto, however, unlike what is illustrated in FIG. 7, in an embodiment, the dam DMM may be composed of a single layer or two layers, or the dam DMM may include four or more layers.

In an embodiment, the lower inorganic encapsulation pattern LIL, the organic encapsulation film OL, and the upper inorganic encapsulation film UIL may be disposed in the non-display region NDA. The organic encapsulation film OL may extend from the display region DA to a region in which the dam DMM is disposed. The dam DMM may play a role in controlling the flow of monomer when the organic encapsulation film OL is formed. The lower inorganic encapsulation pattern LIL and the upper inorganic encapsulation film UIL may extend from the display region DA to a region, in which the dam DMM is disposed, to cover the dam DMM and may be in contact with each other on the dam DMM to seal the organic encapsulation film OL.

In an embodiment, the display panel DP may further include an additional auxiliary electrode AE-A′. The additional auxiliary electrode AE-A′ may be in contact with the first barrier rib layer L1 of the barrier rib PW. Through this, it is possible to increase an area, in which the first barrier rib layer L1 is in contact with an electrode that provides a driving voltage, and reduce the contact resistance of the first barrier rib layer L1. The additional auxiliary electrode AE-A′ may be formed in the same process, include the same material, and have the same configuration as the anode AE. In another embodiment, the additional auxiliary electrode AE-A′ may be omitted.

FIGS. 8A to 8L are cross-sectional views illustrating steps of a method of manufacturing a display panel, according to an embodiment. In describing FIGS. 8A to 8L, the same/similar reference numerals will be used for the same/similar components as those described with reference to FIGS. 1A to 7, and duplicate descriptions will be omitted.

In an embodiment, the method of manufacturing the display panel may include forming an anode on a base layer, forming a preliminary sacrificial pattern, which includes a metal oxide including indium, zinc, and a first metal including at least one of tin or gallium, on the anode, forming a preliminary pixel defining film covering the anode and the preliminary sacrificial pattern, forming a preliminary barrier rib on the preliminary pixel defining film, etching the preliminary barrier rib to form a barrier rib having a barrier rib opening defined therein, etching the preliminary pixel defining film to form a pixel defining film having a light-emitting opening which is defined therein and which overlaps the barrier rib opening, etching the preliminary sacrificial pattern to form a sacrificial pattern having a sacrificial opening which is defined therein and which overlaps the barrier rib opening and forming a cathode, which comes in contact with a light-emitting pattern and the barrier rib, in the barrier rib opening.

In an embodiment and referring to FIG. 8A, the method of manufacturing the display panel may include providing a preliminary display panel DP-I. The preliminary display panel DP-I may include a base layer BL, a circuit element layer DP-CL, an anode AE, a preliminary sacrificial pattern SP-I, and a preliminary pixel defining film PDL-I.

In an embodiment, the providing of the preliminary display panel DP-I may include forming the anode AE on the base layer BL, forming the preliminary sacrificial pattern SP-J on the anode AE, and forming the preliminary pixel defining film PDL-I that covers the anode AE and the preliminary sacrificial pattern SP-I. In addition, the providing of the preliminary display panel DP-I may include forming the circuit element layer DP-CL on the base layer BL prior to the forming of the anode AE.

In an embodiment, in the circuit element layer DP-CL, an insulating layer, a semiconductor layer, and a conductive layer may be formed by a method such as coating and deposition, and then the insulating layer, the semiconductor layer, and the conductive layer may be selectively patterned through photolithography and etching processes to form a semiconductor pattern, a conductive pattern, a signal line, and the like.

In an embodiment, the anode AE may be formed on the circuit element layer DP-CL. The anode AE may be formed by using various methods, such as a deposition process or a sputtering process.

In an embodiment, the preliminary sacrificial pattern SP-J may be formed on the anode AE. The preliminary sacrificial pattern SP-J may be formed by using various methods such as a deposition process or a sputtering process. The preliminary sacrificial pattern SP-J may be disposed directly on the anode AE. The lower surface of the preliminary sacrificial pattern SP-J may be in contact with the upper surface of the anode AE.

In an embodiment, the preliminary sacrificial pattern SP-I may include a first metal, indium, and zinc. The description of the first metal given above with reference to FIG. 5A may be equally applied to the first metal included in the preliminary sacrificial pattern SP-I. The anode AE and the preliminary sacrificial pattern SP-I may be formed through the same patterning process as each other.

In an embodiment, the preliminary pixel defining film PDL-I may be formed on the anode AE and the preliminary sacrificial pattern SP-I. The preliminary pixel defining film PDL-I may cover both the anode AE and the preliminary sacrificial pattern SP-I.

Referring to FIG. 8B, the method of manufacturing the display panel, according to an embodiment, may include forming a first preliminary barrier rib layer L1-I on the preliminary pixel defining film PDL-I. The forming of the first preliminary barrier rib layer L1-I may be performed through a deposition process of a conductive material. In an embodiment, the conductive material that forms the first preliminary barrier rib layer L1-I may include a low-resistance metal. For example, the conductive material that forms the first preliminary barrier rib layer L1-I may be gold (Au), silver (Ag), aluminum (Al), magnesium (Mg), lithium (Li), molybdenum (Mo), copper (Cu), or an alloy thereof. The conductive material that forms the first preliminary barrier rib layer L1-I may be aluminum (Al).

In an embodiment and referring to FIG. 8C, the method of manufacturing the display panel may include forming a second preliminary barrier rib layer L2-I on the first preliminary barrier rib layer L1-I to form a preliminary barrier rib PW-I.

In an embodiment, the forming of the second preliminary barrier rib layer L2-I may be performed through a deposition process of a conductive material. In an embodiment, the conductive material that forms the second preliminary barrier rib layer L2-I may be a metal material. For example, the conductive material that forms the second preliminary barrier rib layer L2-I may be gold (Au), silver (Ag), aluminum (Al), magnesium (Mg), lithium (Li), molybdenum (Mo), titanium (Ti), copper (Cu), or an alloy thereof. The metal that forms the second preliminary barrier rib layer L2-I may be different from the metal that forms the first preliminary barrier rib layer L1-I. The metal that forms the second preliminary barrier rib layer L2-I may be, for example, titanium (Ti).

In an embodiment, the second preliminary barrier rib layer L2-I may not include a metal material. The second preliminary barrier rib layer L2-I may be formed of a silicon-based compound. For example, the second preliminary barrier rib layer L2-I may include at least any one of silicon oxide (SiOₓ), silicon nitride (SiNₓ), or silicon oxynitride (SiOₓN_{y}).

In an embodiment, the preliminary barrier rib PW-I may include a first preliminary barrier rib layer L1-I and a second preliminary barrier rib layer L2-I.

In an embodiment and referring to FIGS. 8D to 8F, the method of manufacturing the display panel may include etching the preliminary barrier rib PW-I to form a barrier rib PW having a barrier rib opening OP-P defined therein. The forming of the barrier rib PW may include forming a first photoresist layer PR1 on the preliminary barrier rib PW-I and etching the first preliminary barrier rib layer L1-I and the second preliminary barrier rib layer L2-I.

In an embodiment and referring to FIG. 8D, the method of manufacturing the display panel may include forming a first photoresist layer PR1 on the preliminary barrier rib PW-I. The first photoresist layer PR1 may be formed by forming a preliminary photoresist layer on the preliminary barrier rib PW-I and then patterning the preliminary photoresist layer by using a photo mask. Through the patterning process, a photo opening OP-PR overlapping the anode AE may be formed in the first photoresist layer PR1.

In an embodiment and referring to FIGS. 8E and 8F, the method of manufacturing the display panel may include etching the first preliminary barrier rib layer L1-I and the second preliminary barrier rib layer L2-I to form a barrier rib PW from the preliminary barrier rib PW-I. The etching of the preliminary barrier rib PW-I may be performed twice. The etching of the first preliminary barrier rib layer L1-I and the second preliminary barrier rib layer L2-I may include a primary etching step and a secondary etching step.

In an embodiment and referring to FIG. 8E, the primary etching step of the first preliminary barrier rib layer L1-I and the second preliminary barrier rib layer L2-I may include dry-etching the first preliminary barrier rib layer L1-I and the second preliminary barrier rib layer L2-I with the use of the first photoresist layer PR1 as a mask. Since the first preliminary barrier rib layer L1-I and the second preliminary barrier rib layer L2-I are formed of a metal material, the primary dry etching process may be easily performed.

In an embodiment, the primary dry etching process may be performed in an etching environment in which the etching selectivities of the first preliminary barrier rib layer L1-I and the second preliminary barrier rib layer L2-I are substantially the same as each other. Accordingly, the inner side surface of the first preliminary barrier rib layer L1-I and the inner side surface of the second preliminary barrier rib layer L2-I, which define a preliminary barrier rib opening OP-PI, may be substantially aligned with each other.

In an embodiment and referring to FIG. 8F, after the primary etching step of the first preliminary barrier rib layer L1-I and the second preliminary barrier rib layer L2-I, the secondary etching step of the first preliminary barrier rib layer L1-I may be performed. The secondary etching step of the first preliminary barrier rib layer L1-I may include forming a barrier rib opening OP-P by wet-etching the first preliminary barrier rib layer L1-I with the use of the first photoresist layer PR1 as a mask. In this specification, the secondary etching step of the first preliminary barrier rib layer L1-I may be referred to as an “undercut etching process”.

In an embodiment and referring to FIG. 8G, a first barrier rib layer L1 and a second barrier rib layer L2 may be formed in the primary etching step of the first preliminary barrier rib layer L1-I. As the first preliminary barrier rib layer L1-I is selectively etched in the secondary etching step of the first preliminary barrier rib layer L1-I, the inner side surface of the barrier rib PW may have an undercut shape on a cross section. A tip portion may be formed in the barrier wall PW by a protruding portion of the second barrier rib layer L2 which protrudes toward the center of the anode AE when compared to the first barrier rib layer L1.

In an embodiment, the barrier rib opening OP-P may include a first region A1 (see FIG. 8F) and a second region A2 (see FIG. 8F) sequentially arranged in a thickness direction (i.e., in the third direction DR3). The first barrier rib layer L1 may include a first inner side surface S1-P defining a portion of the first region A1 of the barrier rib opening OP-P, and the second barrier rib layer L2 may include a second inner side surface S2-P defining the second region A2.

In an embodiment, the secondary wet etching process may be performed in an environment in which the etching selectivity between the first preliminary barrier rib layer L1-I and the second preliminary barrier rib layer L2-I is high. Accordingly, the inner side surface of the barrier rib PW defining the barrier rib opening OP-P may have an undercut shape on a cross section. Specifically, as the etch rate of the first barrier rib layer L1 with respect to an etching solution is greater than the etch rate of the second barrier rib layer L2, the degree of etching of the first barrier rib layer L1 may be greater than that of the second barrier rib layer L2. Accordingly, the first inner side surface S1-P of the first barrier rib layer L1 may be formed to be recessed more inward than the second inner side surface S2-P of the second barrier rib layer L2. A tip portion may be formed in the barrier wall PW by a protruding portion of the second barrier rib layer L2 which protrudes toward the center of the anode AE when compared to the first barrier rib layer L1.

In an embodiment and referring to FIGS. 8F and 8G, the method of manufacturing the display panel may include etching a preliminary pixel defining film PDL-I to form a pixel defining film PDL. The etching process of the preliminary pixel defining film PDL-I may be performed by using a dry etching method, and the etching process may be performed by using the first photoresist layer PR1 and a portion of the barrier rib PW, that is, the second barrier rib layer L2 as a mask. A light-emitting opening OP-E corresponding to the barrier rib opening OP-P may be formed in the pixel defining film PDL.

In an embodiment and referring to FIG. 8H, the method of manufacturing the display panel may include etching a preliminary sacrificial pattern SP-I. The etching process of the preliminary sacrificial pattern SP-I may be performed by using a wet etching method, and the etching process may be performed by using the first photoresist layer PR1 and a portion of the barrier rib PW, that is, the second barrier rib layer L2 as a mask.

In an embodiment, the etching of the preliminary sacrificial pattern SP-I may include etching the preliminary sacrificial pattern SP-I by providing an etching solution to the preliminary sacrificial pattern SP-I.

In an embodiment, the preliminary sacrificial pattern SP-I may include a first metal, indium, and zinc. The description of the first metal given above with reference to FIG. 5A may be equally applied to the first metal included in the preliminary sacrificial pattern SP-I. When the preliminary sacrificial pattern SP-I includes the first metal, the preliminary sacrificial pattern SP-I may maintain an amorphous form in the etching process of the preliminary sacrificial pattern SP-I and therefore may have a high etching selectivity with respect to the anode AE.

In an embodiment, referring again to FIGS. 8G and 8H, forming a sacrificial pattern SP may be performed by etching the preliminary sacrificial pattern SP-I. The sacrificial pattern SP having a sacrificial opening OP-S defined therein may be formed by removing one region of the preliminary sacrificial pattern SP-I through a wet etching process. The sacrificial opening OP-S may be formed through the sacrificial pattern SP and may expose a portion of the upper surface of the anode AE.

In an embodiment, the preliminary sacrificial pattern SP-I may include a first metal-indium-zinc oxide. In an embodiment, the preliminary sacrificial pattern SP-J may include an indium tin zinc oxide (ITZO). For example, the preliminary sacrificial pattern SP-J may be composed of an indium tin zinc oxide (ITZO). In another embodiment, the preliminary sacrificial pattern SP-J may include an indium gallium zinc oxide (IGZO). For example, the preliminary sacrificial pattern SP-J may be composed of an indium gallium zinc oxide (IGZO). In another embodiment, the preliminary sacrificial pattern SP-J may include an indium gallium tin zinc oxide (IGTZO). For example, the preliminary sacrificial pattern SP-J may be composed of an indium gallium tin zinc oxide (IGTZO).

In an embodiment, the content of the first metal with respect to the total content of metal elements included in the preliminary sacrificial pattern SP-I may be about 5 at % or more. The content of the first metal with respect to the total content of the first metal, indium, and zinc included in the preliminary sacrificial pattern SP-I may be about 5 at % or more. For example, the content of the first metal with respect to the total content of the first metal, indium, and zinc included in the preliminary sacrificial pattern SP-I may be about 5 at % to about 30 at %.

In an embodiment, the content ratio of indium to zinc in the preliminary sacrificial pattern SP-I may be about 4:6 to about 6:4. For example, the content ratio of indium to zinc in the preliminary sacrificial pattern SP-I may be about 5:5.

In an embodiment, the metal oxide included in the preliminary sacrificial pattern SP-I may include an amorphous structure. The metal oxide included in the preliminary sacrificial pattern SP-I may have an amorphous structure. In an embodiment, the preliminary sacrificial pattern SP-I may include an amorphous indium tin zinc oxide (a-ITZO), an amorphous indium gallium zinc oxide (a-IGZO), or an amorphous indium gallium tin zinc oxide (a-IGTZO). For example, the preliminary sacrificial pattern SP-I may be made of an amorphous indium tin zinc oxide (a-ITZO), an amorphous indium gallium zinc oxide (a-IGZO), or an amorphous indium gallium tin zinc oxide (a-IGTZO).

The etching solution for etching the preliminary sacrificial pattern SP-I is not limited, but may be, in an embodiment, an acid-based etching solution. In an embodiment, the acid-based etching solution may include at least one of an organic acid-based etching solution or an inorganic acid-based etching solution. The organic acid-based etching solution may be, for example, oxalic acid. The inorganic acid-based etching solution may include a phosphoric acid etching solution or a hydrogen peroxide etching solution. For example, the inorganic acid-based etching solution may be an etching solution including phosphoric acid, nitric acid, and acetic acid. In addition, the inorganic acid-based etching solution may further include substances besides phosphoric acid, nitric acid, and acetic acid.

In an embodiment, the etching process of the preliminary sacrificial pattern SP-I may be performed in an environment in which the etch selectivity between the preliminary sacrificial pattern SP-I and the anode AE is high, and through this, it is possible to prevent the anode AE from being etched together. That is, by disposing the preliminary sacrificial pattern SP-I, which has a higher etch rate than the anode AE, between the pixel defining film PDL and the anode AE, it is possible to prevent the anode AE from being etched together and damaged during the etching process.

In an embodiment, the etch rate of the preliminary sacrificial pattern SP-I and the etch rate of the anode AE may be different from each other. The anode AE may be configured to be etched at a first etch rate, and the preliminary sacrificial pattern SP-I may be configured to be etched at a second etch rate which is greater than the first etch rate. In the etching process of the preliminary sacrificial pattern SP-I, the anode AE is not etched or may not be substantially etched due to the etch rate of the preliminary sacrificial pattern SP-I which is greater than that of the anode AE. In an embodiment, the etch rate of the preliminary sacrificial pattern SP-I may be about 1.0 Å/s to about 30.0 Å/s. The etch rate of the preliminary sacrificial pattern SP-I may be achieved by controlling the content of the first metal with respect to the total content of metal elements included in the preliminary sacrificial pattern SP-I.

In an embodiment, the preliminary sacrificial pattern SP-I and the anode AE may have different degrees of crystallinity at a first temperature. In an embodiment, the preliminary sacrificial pattern SP-I may have a first degree of crystallinity at the first temperature, and the anode AE may have a second degree of crystallinity greater than the first degree of crystallinity at the first temperature. For example, the preliminary sacrificial pattern SP-I may have an amorphous structure at the first temperature, and the anode AE may have a crystalline structure at the first temperature. Meanwhile, in this specification, the first temperature may be about 250° C. “Crystallinity” may be expressed by Equation 2 below.

$$Degree of crystallinity = {P}_{1} / ( {P}_{1} + {P}_{2} ) , \qquad [ Equation 2 ]$$

where in Equation 2 above, P₁ refers to a total sum of crystalline peak areas in an X-ray diffraction (XRD) pattern, and P₂ refers to a total sum of amorphous peak areas in the X-ray diffraction pattern.

In a process of manufacturing the display device according to an embodiment, the preliminary sacrificial pattern SP-I may be exposed to a high temperature condition and the amorphous structure of the metal oxide of the preliminary sacrificial pattern SP-J may be partially crystallized due to the high temperature. When the metal oxide included in the preliminary sacrificial pattern SP-I is crystallized, it may be difficult to obtain a pattern desired by the sacrificial pattern SP as the etching selectivity with respect to the anode AE is reduced in the etching process of the preliminary sacrificial pattern SP-I. When the preliminary sacrificial pattern SP-J includes the first metal, the metal oxide included in the preliminary sacrificial pattern SP-J may maintain an amorphous structure in the etching process of the preliminary sacrificial pattern SP-I, thereby being able to increase the etching selectivity with respect to the anode AE having a crystalline structure. For example, in the etching of the preliminary sacrificial pattern SP-I, selective etching may occur between the anode AE having a crystalline structure and the preliminary sacrificial pattern SP-J having an amorphous structure. Accordingly, the preliminary sacrificial pattern SP-J having an amorphous structure may be etched and the anode AE having a crystalline structure may remain.

In an embodiment, the etch rate of the sacrificial pattern SP with respect to the etching solution may be reduced by adding the first metal to the indium tin oxide included in the sacrificial pattern SP, thereby being able to prevent a void from occurring in the sacrificial pattern SP during etching. The void formed in the sacrificial pattern SP may be defined as a void formed between the anode AE and the pixel defining film PDL as the inner side surface of the sacrificial pattern SP is recessed compared to the inner side surface of the pixel defining film as a result of excessive etching of the sacrificial pattern SP. When foreign substances enter such a void during a manufacturing process or use of the display device, a pixel defect, or an afterimage or stain may occur in the display region. According to an embodiment, since the sacrificial pattern SP includes the first metal, the formation of a void in the sacrificial pattern SP may be suppressed by controlling the etch rate, thereby preventing a pixel defect from occurring. Accordingly, the reliability of the display device DD may be improved.

In an embodiment, referring again to FIG. 8H, a sacrificial opening OP-S overlapping the light-emitting opening OP-E may be formed in the sacrificial pattern SP formed by etching the preliminary sacrificial pattern SP-I. At least a portion of the anode AE may be exposed from the sacrificial pattern SP and the pixel defining film PDL through the sacrificial opening OP-S and the light-emitting opening OP-E.

In an embodiment, the etching process of the sacrificial pattern SP may be performed in an environment in which the etching selectivity between the sacrificial pattern SP and the first and second barrier rib layers L1 and L2, respectively, of the barrier rib PW is high, and through this, it is possible to prevent the first and second barrier rib layers L1 and L2, respectively, from being etched together.

In an embodiment, the sacrificial opening OP-S defined in the sacrificial pattern SP may have a first width Wₛ. The light-emitting opening OP-P defined in the pixel defining film PDL may have a second width Wₚ. In an embodiment, the first width Wₛ of the sacrificial opening OP-S may be smaller than the second width Wₚ of the light-emitting opening OP-P. That is, the inner side surface of the sacrificial pattern SP may be disposed closer to the center of the anode AE than the inner side surface of the pixel defining film PDL. Without being limited thereto, however, unlike what is illustrated in FIG. 8H, the first width Wₛ of the sacrificial opening OP-S may be substantially equal to the second width Wₚ of the light-emitting opening OP-P. That is, the inner side surface of the sacrificial pattern SP may be aligned with the inner side surface of the pixel defining film PDL.

In an embodiment, when the first width Wₛ of the sacrificial opening OP-S is greater than the second width Wₚ of the light-emitting opening OP-P, a void may be formed between the anode AE and the pixel defining film PDL, thereby causing an image defect. Therefore, it is necessary to control the first width Wₛ of the sacrificial opening OP-S so as to be equal to or less than the second width Wₚ of the light-emitting opening OP-P. When the first width Wₛ of the sacrificial opening OP-S is controlled so as to be equal to or less than the second width Wₚ of the light-emitting opening OP-P, a defect due to the occurrence of a void may be prevented. Accordingly, the reliability of the display device DD may be further improved.

In an embodiment, referring to FIGS. 8H and 8I, the method of manufacturing the display panel may include removing a first photoresist layer PR1, forming a light-emitting pattern EP, forming a cathode CE, and forming a capping pattern CP.

In an embodiment, each of the forming of the light-emitting pattern EP, the forming of the cathode CE, and the forming of the capping pattern CP may be performed through a deposition process. In an embodiment, the forming of the light-emitting pattern EP may be performed through a thermal evaporation process, the forming of the cathode may be performed through a sputtering process, and the forming of the capping pattern CP may be performed through a thermal evaporation process. However, the invention is not limited thereto.

In an embodiment, in the forming of the light-emitting pattern EP, the light-emitting pattern EP may be separated by a tip portion formed in the barrier rib PW and may be disposed in the light-emitting opening OP-E and the barrier rib opening OP-P. In the forming of the light-emitting pattern EP, a first preliminary dummy pattern D1-I spaced apart from the light-emitting pattern EP may be formed together on the barrier rib PW. The light-emitting pattern EP may be formed on the anode AE. The light-emitting pattern EP may be disposed on a portion (hereinafter referred to as a sacrificial open portion) of the sacrificial pattern SP exposed through the light-emitting opening OP-E. The light-emitting pattern EP may be disposed on the anode AE and the sacrificial open portion. The light-emitting pattern EP may cover the upper surface of the anode AE and the sacrificial open portion which are exposed through the sacrificial opening OP-S. In an embodiment, the light-emitting pattern EP may be in contact with the sacrificial open portion of the sacrificial pattern SP.

In an embodiment, in the forming of the cathode CE, the cathode CE may be separated by a tip portion formed in the barrier rib PW and be disposed in the barrier rib opening OP-P. Compared to the light-emitting pattern EP, the cathode CE may be provided at a high incident angle and may be formed to be in contact with the first inner side surface S1-P of the first barrier rib layer L1. In the forming of the cathode CE, a second preliminary dummy pattern D2-I spaced apart from the cathode CE may be formed together on the barrier rib PW. The anode AE, the light-emitting pattern EP, and the cathode CE may constitute a light-emitting element ED.

In an embodiment, in the forming of the capping pattern CP, the capping pattern CP may be separated by a tip portion formed in the barrier rib PW and may be disposed in the barrier rib opening OP-P. In the forming of the capping pattern CP, a third preliminary dummy pattern D3-I spaced apart from the capping pattern CP may be formed together on the barrier rib PW. Meanwhile, according to another embodiment, the forming of the capping pattern CP may be omitted.

In an embodiment, the first to third preliminary dummy patterns D1-I, D2-I, and D3-I, respectively, form a preliminary dummy pattern DMP-I, and a dummy opening OP-D may be formed in the preliminary dummy pattern DMP-I. The dummy opening OP-D may include a first opening region AA1, a second opening region AA2, and a third opening region AA3 which are sequentially arranged in a thickness direction (i.e., in the third direction DR3). The first opening region AA1 of the dummy opening OP-D may be defined by the inner side surface of the first dummy pattern D1, the second opening region AA2 may be defined by the inner side surface of the second dummy pattern D2, and the third opening region AA3 may be defined by the inner side surface of the third dummy pattern D3.

In an embodiment and referring to FIG. 8J, the method of manufacturing the display panel may include forming a preliminary lower inorganic encapsulation pattern LIL-I. The preliminary lower inorganic encapsulation pattern LIL-I may be formed through a deposition process. In an embodiment, the preliminary lower inorganic encapsulation pattern LIL-I may be formed through a chemical vapor deposition (CVD) process. The preliminary lower inorganic encapsulation pattern LIL-I may be formed on the barrier rib PW and the cathode CE, and a portion of the preliminary lower inorganic encapsulation pattern LIL-I may be formed on the inside of the barrier rib opening OP-P.

In an embodiment and referring to FIG. 8K, the method of manufacturing the display panel may include forming a second photoresist layer PR2, patterning a preliminary lower inorganic encapsulation pattern LIL-1 (see FIG. 8J) to form the lower inorganic encapsulation pattern LIL, and patterning the preliminary dummy patterns DMP-I (see FIG. 8J) to form the dummy patterns DMP.

In an embodiment, in the forming of the second photoresist layer PR2, the second photoresist layer PR2 may be formed by forming a preliminary photoresist layer and then patterning the preliminary photoresist layer by using a photo mask. Through the patterning process, the second photoresist layer PR2 may be formed in a pattern shape corresponding to the light-emitting opening OP-E.

In an embodiment and referring to FIGS. 8J and 8K, the patterning of the preliminary lower inorganic encapsulation pattern LIL-I may include patterning the preliminary lower inorganic encapsulation pattern LIL-I by dry-etching the preliminary lower inorganic encapsulation pattern LIL-I so that a portion of the preliminary lower inorganic encapsulation pattern LIL-I, which overlaps remaining anodes AE except corresponding anodes AE, is removed. For example, when the preliminary lower inorganic encapsulation pattern LIL-I corresponds to the first anode AE1 (see FIG. 6), a portion of the preliminary lower inorganic encapsulation pattern LIL-I overlapping the second and third anodes AE2 and AE3 (see FIG. 6) may be removed.

In an embodiment, a lower inorganic encapsulation pattern LIL overlapping a corresponding light-emitting opening OP-E may be formed from the patterned preliminary lower inorganic encapsulation pattern LIL-I. A portion of the lower inorganic encapsulation patterns LIL may be disposed in the barrier rib opening OP-P to cover the light-emitting element ED, and another portion of the lower inorganic encapsulation pattern LIL may be disposed on the barrier rib PW.

In an embodiment, the patterning of the preliminary dummy patterns DMP-I may include patterning the first to third preliminary dummy patterns D1-I, D2-I, and D3-I, respectively, by dry-etching the first to third preliminary dummy patterns D1-I, D2-I, and D3-I, respectively, so that a portion of the first to third preliminary dummy patterns D1-I, D2-I, and D3-I, respectively, which overlaps remaining anodes AE except corresponding anodes AE, is removed. For example, when the first to third preliminary dummy patterns D1-I, D2-I, and D3-I, respectively, correspond to the first anode AE1 (see FIG. 6), portions of the first to third preliminary dummy patterns D1-I, D2-I, and D3-I, respectively, which overlap the second and third anodes AE2 and AE3, respectively (see FIG. 6), may be removed.

In an embodiment, first to third dummy patterns D1, D2 and D3, respectively, overlapping a corresponding light-emitting opening OP-E may be formed from the patterned first to third preliminary dummy patterns D1-I, D2-I, and D3-I, respectively, so that the dummy patterns DMP including the first to third dummy patterns D1, D2 and D3, respectively, may be formed. The first to third dummy patterns D1, D2, and D3, respectively, may have a closed-line shape surrounding a corresponding light-emitting region PXA (see FIG. 5A) on a plane.

In an embodiment and referring to FIG. 8L, the method of manufacturing the display panel may include completing the display panel by removing the second photoresist layer PR2 (see FIG. 8K) and then forming the organic encapsulation film OL and the upper inorganic encapsulation film UIL. The organic encapsulation film OL may be formed by applying an organic material by an inkjet method, but the invention is not limited thereto. The organic encapsulation film OL provides a flat upper surface. Hereafter, the upper inorganic encapsulation film UIL may be formed by depositing an inorganic material. Through this, the display panel DP including a base layer BL, a circuit element layer DP-CL, a display element layer DP-OLED, and a thin film encapsulation layer TFE may be formed.

In an embodiment, between the forming of the lower inorganic encapsulation pattern LIL and the completion of the display panel DP, forming a barrier rib opening and a light-emitting opening corresponding to a light-emitting region of a different color in the barrier rib PW and the pixel defining film PDL, forming light-emitting elements configured to provide different colors, and forming a lower inorganic encapsulation pattern covering the light-emitting elements configured to provide different colors may be further performed. Through this, as illustrated in FIG. 6, the display panel DP including the first to third light-emitting elements ED1, ED2, and ED3, respectively, the first to third capping patterns CP1, CP2, and CP3, respectively, the (1-1)-th to (1-3)-th dummy patterns D1-1, D1-2, and D1-3, respectively, the (2-1)-th to (2-3)-th dummy patterns D2-1, D2-2, and D2-3, respectively, the (3-1) to (3-3)-th dummy patterns D3-1, D3-2, and D3-3, respectively, and the first to third lower inorganic encapsulation patterns LIL1, LIL2, and LIL3, respectively, may be formed.

The display panel according to an embodiment may prevent the sacrificial pattern from being excessively etched in the etching of the sacrificial pattern, thereby improving the process reliability of the display panel.

Although the above has been described with reference to embodiments of the invention, those skilled in the art or those of ordinary skill in the art will understand that various modifications and changes can be made to the invention within the scope that does not depart from the spirit and technical field of the invention. Accordingly, it will be understood that the invention should not be limited to these embodiments. Moreover, the embodiments or parts of the embodiments may be combined in whole or in part without departing from the scope of the invention.

What is claimed is:

1. A display panel comprising:
a base layer;
an anode disposed on the base layer;
a sacrificial pattern disposed on the anode and having a sacrificial opening which is defined therein and which exposes a portion of the upper surface of the anode;
a pixel defining film disposed on the base layer to cover at least a portion of the sacrificial pattern and having a light-emitting opening which is defined therein and which corresponds to the sacrificial opening;
a barrier rib disposed on the pixel defining film and having a barrier rib opening which is defined therein and which corresponds to the light-emitting opening;
a light-emitting pattern disposed on the anode in the barrier rib opening; and
a cathode disposed on the light-emitting pattern and in contact with the barrier rib,
wherein:
the sacrificial pattern comprises a metal oxide which includes a first metal, indium, and zinc, the first metal including at least one of tin or gallium; and
the sacrificial pattern has a shape protruding from one side of the pixel defining film.

2. The display panel of claim 1, wherein the width of the sacrificial opening is smaller than the width of the light-emitting opening.

3. The display panel of claim 1, wherein the content of the first metal included in the sacrificial pattern is about 5.0 at % or more of the total content of the first metal, the indium, and the zinc included in the sacrificial pattern.

4. The display panel of claim 1, wherein the sacrificial pattern comprises an indium tin zinc oxide (ITZO) or an indium gallium zinc oxide (IGZO).

5. The display panel of claim 4, wherein the metal oxide included in the sacrificial pattern comprises an amorphous structure.

6. The display panel of claim 1, wherein, among the total content of the first metal, the indium, and the zinc included in the sacrificial pattern:
the content of the indium is about 35 at % to about 50 at %; and
the content of the zinc is about 35 at % to about 50 at %.

7. The display panel of claim 1, wherein the content ratio of the indium to the zinc included in the sacrificial pattern is about 4:6 to about 6:4.

8. The display panel of claim 1, wherein the anode comprises an indium tin oxide (ITO).

9. The display panel of claim 1, wherein the anode comprises:
a first layer disposed on the base layer and comprising an indium tin oxide (ITO);
a second layer disposed on the first layer and comprising silver; and
a third layer disposed on the second layer and comprising an indium tin oxide (ITO),
wherein the sacrificial pattern is directly disposed on the third layer.

10. The display panel of claim 1, wherein the light-emitting opening exposes a portion of the upper surface of the sacrificial pattern, and
wherein the portion of the upper surface of the sacrificial pattern exposed by the light-emitting opening is in contact with the light-emitting pattern.

11. The display panel of claim 1, wherein the barrier rib comprises:
a first barrier rib layer disposed on the pixel defining film and including a metal; and
a second barrier rib layer disposed on the first barrier rib layer and including a metal or a silicon-based compound.

12. The display panel of claim 11, wherein the cathode is in contact with the first barrier rib layer.

13. The display panel of claim 11, wherein the barrier rib opening comprises:
a first region in which the light-emitting pattern is disposed; and
a second region having a smaller width than the first region,
wherein:
an inner side surface of the first barrier rib layer defines the first region; and
an inner side surface of the second barrier rib layer defines the second region.

14. The display panel of claim 11, wherein the second barrier rib layer has an undercut shape protruding from one side of the first barrier rib layer.

15. The display panel of claim 1, further comprising a thin film encapsulation layer disposed on the light-emitting element and including a plurality of thin films,
wherein the thin film encapsulation layer includes an inorganic encapsulation pattern which covers the light-emitting element and is partially in contact with the barrier rib.

16. A display panel comprising:
a base layer;
an anode disposed on the base layer;
a sacrificial pattern disposed on the anode and having a sacrificial opening which is defined therein and which exposes a portion of the upper surface of the anode;
a pixel defining film disposed on the base layer to cover at least a portion of the sacrificial pattern and having a light-emitting opening which is defined therein and which corresponds to the sacrificial opening;
a barrier rib disposed on the pixel defining film and having a barrier rib opening which is defined therein and which corresponds to the light-emitting opening;
a light-emitting pattern disposed on the anode in the barrier rib opening; and
a cathode disposed on the light-emitting pattern and in contact with the barrier rib,
wherein the sacrificial pattern includes a first metal, indium, and zinc, the first metal including at least one of tin or gallium, and
wherein the content of the first metal included in the sacrificial pattern is about 5.0 at % or more of the total content of the first metal, the indium, and the zinc included in the sacrificial pattern.

17. The display panel of claim 16, wherein an inner side surface of the pixel defining film is disposed closer to the center of the anode than an inner side surface of the sacrificial pattern.

18. The display panel of claim 16, wherein the inner side surface of the pixel defining film is aligned with the inner side surface of the sacrificial pattern.

19. A method for manufacturing a display panel, the method comprising:
forming an anode on a base layer;
forming a preliminary sacrificial pattern, which comprises a metal oxide comprising indium, zinc, and a first metal comprising at least one of tin or gallium, on the anode;
forming a preliminary pixel defining film covering the anode and the preliminary sacrificial pattern;
forming a preliminary barrier rib on the preliminary pixel defining film;
etching the preliminary barrier rib to form a barrier rib having a barrier rib opening defined therein;
etching the preliminary pixel defining film to form a pixel defining film having a light-emitting opening defined therein and overlapping the barrier rib opening;
etching the preliminary sacrificial pattern to form a sacrificial pattern having a sacrificial opening defined therein and overlapping the barrier rib opening; and
forming a cathode, which comes in contact with a light-emitting pattern and the barrier rib, in the barrier rib opening,
wherein, in the forming of the sacrificial pattern, the sacrificial pattern is formed to protrude from one side of the pixel defining film.

20. The method of claim 19, wherein, in the forming of the sacrificial pattern, an etch rate of the anode is lower than an etch rate of the preliminary sacrificial pattern.
